(19) United States
(12) Patent Application Publication
(10) Pub. No.: US 2024/0203869 A1
(43) Pub. Date: Jun. 20, 2024

(54) INTEGRATED CIRCUIT DEVICES WITH HYBRID METAL LINES

(71) Applicant: Intel Corporation, Santa Clara, CA (US)

(72) Inventors: Sukru Yemenicioglu, Portland, OR (US); Leonard P. Guler, Hillsboro, OR (US); Nikhil Jasvant Mehta, Portland, OR (US); Charles Henry Wallace, Portland, OR (US)

(73) Assignee: Intel Corporation, Santa Clara, CA (US)

(21) Appl. No.: 18/067,031

(22) Filed: Dec. 16, 2022

(51) Int. Cl. H01L 23/522; H01L 21/768; H01L 23/532

(52) U.S. Cl. CPC H01L 23/5226; H01L 21/76892; H01L 23/53228; H01L 23/53257

(57) ABSTRACT

Methods for fabricating an integrated circuit (IC) device with one or more hybrid metal lines are provided. An example IC device includes a substrate; and a metal line extending, along an axis, over the substrate. The metal line has a first end and a second end along the axis. A portion of the metal line at the first end includes a first electrically conductive material. Another portion of the metal line includes a second electrically conductive material, where the second electrically conductive material is different from the first electrically conductive material. In some instances, the first electrically conductive material is a low-resistive, electrically conductive material, and the second electrically conductive material is a direct etch-compatible, electrically conductive material.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a flow diagram of an example method of fabricating an integrated circuit (IC) device with hybrid metal lines using a plug last metal cut technique, in accordance with various embodiments of the present disclosure.

FIGS. 2A-2I illustrate top-down views and cross-sectional side views at various stages in the manufacture of an example IC device according to the method of FIG. 1, in accordance with some embodiments, in accordance with various embodiments of the present disclosure.

FIGS. 3A-3C illustrate perspective views and a cross-sectional side view at various stages in the manufacture of an example IC device according to the method of FIG. 1, in accordance with some embodiments, in accordance with various embodiments of the present disclosure.

FIG. 4 illustrates top views of a wafer and dies that include hybrid metal lines, in accordance with any of the embodiments of the present disclosure.

FIG. 5 is a cross-sectional side view of an IC package that may include one or more IC devices with hybrid metal lines, in accordance with any of the embodiments of the present disclosure.

FIG. 6 is a cross-sectional side view of an IC device assembly that may include one or more IC devices with hybrid metal lines, in accordance with any of the embodiments of the present disclosure.

FIG. 7 is a block diagram of an example computing device that may include one or more IC devices with hybrid metal lines, in accordance with any of the embodiments of the present disclosure.

FIG. 8 is a block diagram of an example radio frequency (RF) device that may include one or more IC devices with hybrid metal lines, in accordance with any of the embodiments of the present disclosure.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating hybrid metal lines integrated in a back-end-of-line (BEOL) interconnect layer as described herein, it might be useful to first understand phenomena that may come into play during IC fabrication. The following foundational information may be viewed as a basis from which the present disclosure may be properly explained. Such information is offered for purposes of explanation only and, accordingly, should not be construed in any way to limit the broad scope of the present disclosure and its potential applications.

ICs commonly include electrically conductive microelectronic structures, known in the art as interconnects, to provide electrical connectivity between various components or circuit elements. Interconnect may be in the form of one or more metallization layers formed above the components on an IC. Each metallization layer may include a plurality of electrically conductive wires (sometimes referred to as “metal lines,” “metal tracks,” or “metal traces”) which are electrically insulated from one another except for when/where they may need to be electrically connected. In this regard, electrical connections between metal lines of different layers can be realized by means of vias filled and/or lined with one or more electrically conductive materials. Electrical conductivity of a metal line can be disrupted (or interrupted) where needed, e.g., to break up a given metal line into two metal lines electrically isolated from one another. Conventionally, such a disruption can be achieved using a process referred to as “metal cut” since the process involved removal of a portion of a metal line.

In the past, the sizes and the spacing of interconnects such as metal lines and vias have progressively decreased, and it is expected that in the future the sizes and the spacing of the interconnects will continue to progressively decrease, for at least some types of ICs (e.g., advanced microprocessors, chipset components, graphics chips, etc.). One measure of a size of a metal line is the critical dimension of the line width. One measure of a spacing of metal lines is the line pitch, representing the center-to-center distance (along a lateral axis of the metal lines) between the closest adjacent metal lines of a given metallization layer. As discussed above, a metal line can be cut or separated into multiple segments or multiple metal lines. Another measure of a spacing of metal lines is the tightness (along a longitudinal axis of the metal lines) between ends of adjacent metal lines (line segments) resulted from a metal cut.

Currently, metal lines are commonly made of a single material (which may typically be copper due to its low electrical resistivity and high electrical conductivity). That is, these metal lines are monolithic in their composition throughout the lines except at cut regions in which a dielectric material may be filled. With the advancement of technology nodes, the metal line widths and the tightness of metal line end-to-end structures (or metal line end-to-end spacings) are becoming difficult to scale. In particular, the metal line cut size can determine the via landing and coverage, directly impacting yield and performance. As an example, in some advanced technology nodes, a metal line pitch can be 50 nanometers (nm) or less, and it may be desirable to have a metal line end-to-end spacing no greater than 35 nm. While copper metal lines can offer a low electrical resistance, currently available cut methods may be unable to directly etch copper to form short and/or narrow cut regions as required by the reduced metal line widths and/or increased metal line end-to-end tightness. On the other hand, materials that can be etched cleanly, such as, but are not limited to, tungsten, molybdenum, and ruthenium, may not provide an electrical resistance as low as copper. For instance, some of these directly etchable materials can have a resistance that is five times or more than the resistance of copper for a certain metal line width, making them unsuitable for forming metal lines to provide electrical paths in ICs.

To address the issues discussed above, the present disclosure may take advantage of the low resistivity of copper and the direct etching capability of higher resistive materials, such as, but are not limited to, tungsten, molybdenum, and/or ruthenium, to form hybrid metal lines. As used herein, a hybrid metal line may refer to a metal line that is formed from one electrically conductive material that has a low resistivity to provide an electrical path in an IC while another electrically conductive material that has a direct etching capability may be present in a region at an end of the metal line where a metal cut is performed.

The present disclosure may provide techniques for fabricating IC devices with one or more hybrid metal lines, for example, as part of a metallization layer integrated in a BEOL layer over a support structure (e.g., a substrate, a wafer, or a chip). The process of fabricating hybrid metal lines may include creating at least one plug along a line opening (or line trench) where hybrid metal lines are to be formed. A plug may generally refer to a preserved region in which a certain material may not be formed during a certain fabrication process. In the context of forming hybrid metal lines, a plug may be a preserved region in which copper (a low-resistive material to be used for providing electrical paths) may not be formed. The fabrication process may further include filling the one or more plugs with a material that is compatible with direct etch. A direct etch may refer to a direct removal of a portion of a material (e.g., without the need of a plug). The fabrication process may further include filling the remaining portions of the line opening with copper. Subsequently, a cut may be introduced at the filled plug, for example, by performing a final etch to create separate metal lines or line segments (e.g., hybrid metal lines) with a tight end-to-end spacing. As used herein, the process of forming a plug, followed by performing a final etch or cut at the plug may be referred to as a “plug last metal cut” process.

According to embodiments of the present disclosure, an IC device may include a support structure (e.g., a substrate, a wafer, or a chip) and a metal line extending, along an axis, over the support structure. The metal line may have a first end and a second end along the axis, where the second end is opposite the first end. Further, a portion of the metal line at the first end may include a first electrically conductive material and another portion of the metal line (e.g., the remaining portion of the metal line and, in some instances, a portion of the metal line at the second end as well) may include a second electrically conductive material, where the second electrically conductive material is different from the first electrically conductive material. In some embodiments, the second electrically conductive material may be a low-resistive, electrically conductive material such as copper, and the first electrically conductive material may be a material that is compatible with a direct etch process, electrically conductive material, for example, including but limited to, at least one of tungsten, molybdenum, or ruthenium.

In some embodiments, the metal line is one of a plurality of metal lines in a metallization layer over the support structure. For instance, the axis may be a first axis, and the plurality of metal lines may extend, along the first axis, over the support structure and spaced apart from each other along a second axis by an insulator material (e.g., an insulating spacer material), where the first and second axes are about perpendicular to each other and substantially parallel to the support structure. In some embodiments, the plurality of metal lines may be substantially parallel to each other, and a pitch of the plurality of metal lines may be less than 50 nanometers (e.g., between about 16 and 50 nm, 20 and 45 nm, or 20 and 36 nm).

In some embodiments, the metal line is a metal line segment resulted from a “plug last metal cut” process as discussed herein. For instance, the metal line is a first metal line, and the IC device may further include a second metal line extending, along the same axis as the first metal line, over the support structure. The second metal line may be an adjacent segment resulted from the metal cut. As such, the second metal line is separate (disjoint) from the first metal line, and a central longitudinal axis of the first metal line may be aligned to a central longitudinal axis of the second metal line. Further, the second metal line may have a first end and a second end along the axis, where the first end of the second metal line may be closer to the first end of the first metal line than the second end of the second metal line. Similar to the first metal line, a portion of the second metal line at the first end of the second metal line may include the first electrically conductive material (the direct etch-compatible, electrically conductive material), and another portion of the second metal line (e.g., the remaining portion of the second metal line, and in some instances, a portion of the of the second metal line at the second end as well) may include the second electrically conductive material (the low-resistive, electrically conductive material). In other words, the first metal line and the second metal line may respectively correspond to a first segment and a second adjacent segment, and the first end of the first metal line may be spaced apart from the first end of the second metal line, resulting from the metal cut.

In some embodiments, the separation or opening between the first end of the first metal line and the first end of the second metal line may taper down towards the support structure. As such, a distance between the first end of the first metal line and the first end of the second metal line in a first plane parallel to the substrate may be greater than a distance between the first end of the first metal line and the first end of the second metal line in a second plane parallel to the substrate, the second plane being closer to the support structure than the first plane. In some examples, a dimension of the widest portion of the tapered opening along the axis may be less than 35 nm (e.g., between about 5 and 20 nm or between 3 and 25 nm). In some embodiments, the first end of the first metal line and the first end of the second metal line may be spaced apart from each other by an insulator material (e.g., a dielectric material). The tapered opening filled with the insulator material may be referred to as a plug, and the insulator material in the tapered opening may be referred to as an insulating plug material. In some embodiments, the insulator material is a first insulator material, and the IC device may further include a second insulator material (e.g., an insulating interlayer material) between the support structure and the metal line, the tapered opening (resulted from the metal cut) may extend into a portion of the second insulator material, and the first insulator material may at least partially fill the portion of the second insulator material. In some embodiments, the insulator material in the tapered opening is a first insulator material (e.g., an insulating plug material), and at least one of a sidewall of the first metal line or a sidewall of the second metal line along the axis is in contact with a second insulator material (e.g., an insulating spacer material). In some embodiments, the first insulator material may be different from the second insulator material. In other embodiments, the first insulator material may be the same as the second insulator material. In some embodiments, the first insulator material may have a lower dielectric constant than the second insulator material.

Various embodiments of the present disclosure may provide several benefits. For example, combining the resistance of copper and direct etch capability of other higher resistance materials to form hybrid metal lines can allow for formation of short or narrow cut(s) on a low resistance metal line. That is, tight metal line end-to-end spacing (e.g., of less than about 35 nm) can be achieved with low-resistive metal lines, improving yield and performance.

Each of the structures, packages, methods, devices, and systems of the present disclosure may have several innovative aspects, no single one of which being solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “sidewall” may refer to a surface that is designed to be perpendicular to a support structure (e.g., a die, a wafer, a substrate, a package substrate, or a carrier substrate) of the IC device but may not always end up being exactly perpendicular due to manufacturing processes used to fabricate IC devices. Therefore, as used herein, the term “sidewall” refers to a surface that extends away from a support structure of the IC device and that may be substantially perpendicular, within a certain tolerance. In another example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc. Similarly, the terms naming various compounds refer to materials having any combination of the individual elements within a compound (e.g., “gallium arsenide” or “GaAs” may refer to a material that includes Gallium and Arsenic). Further, the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value based on the context of a particular value as described herein or as known in the art.

The term “interconnect” may refer to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The terms such as “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

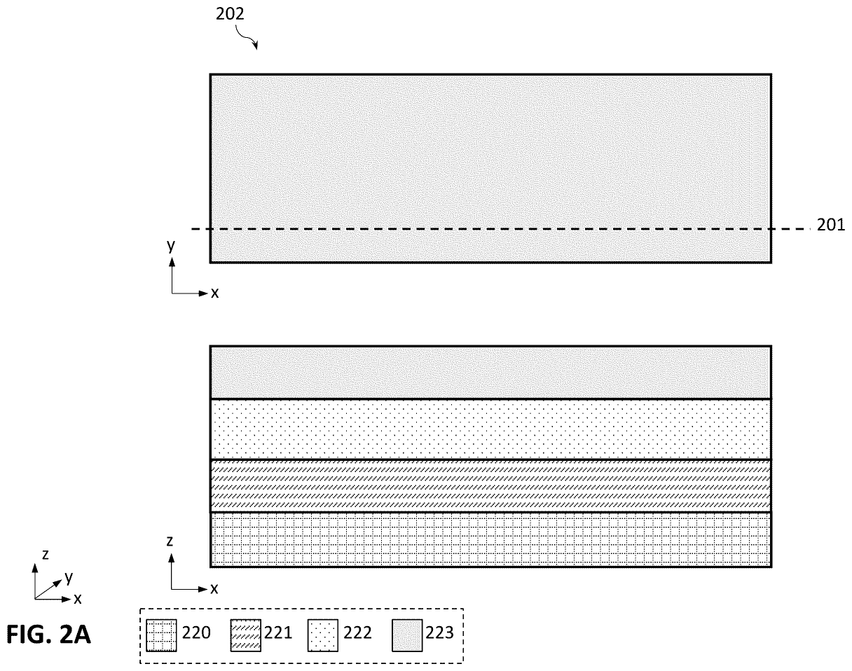

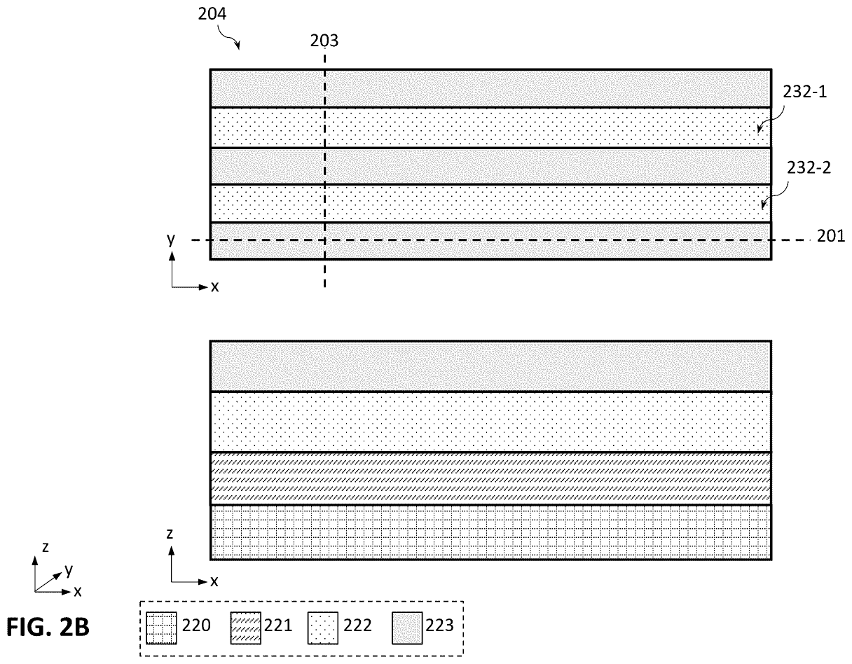

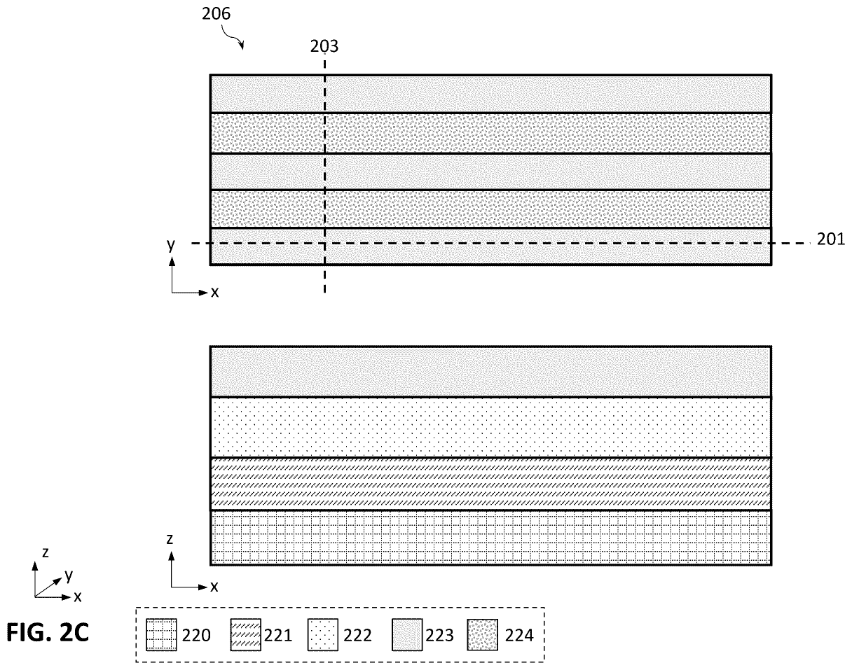

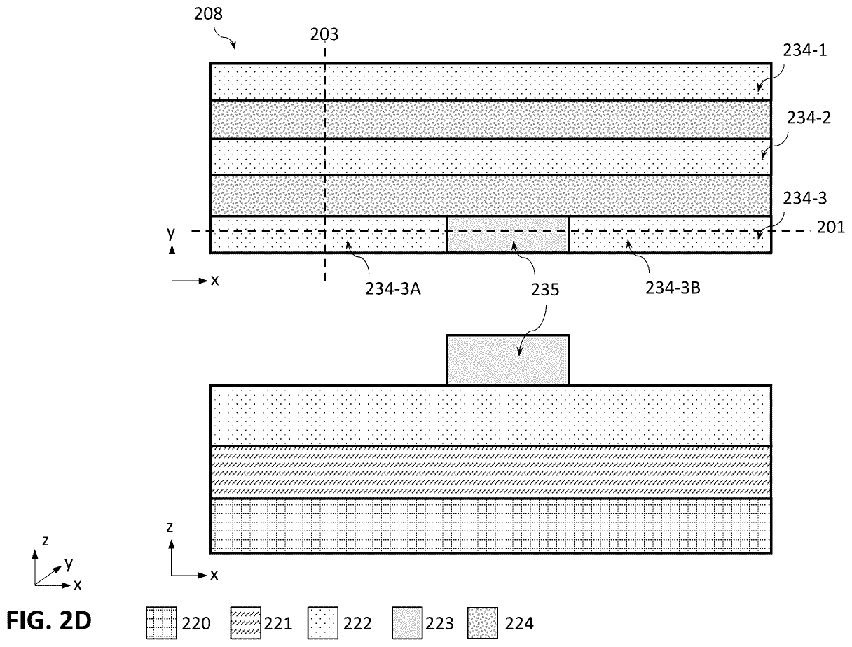

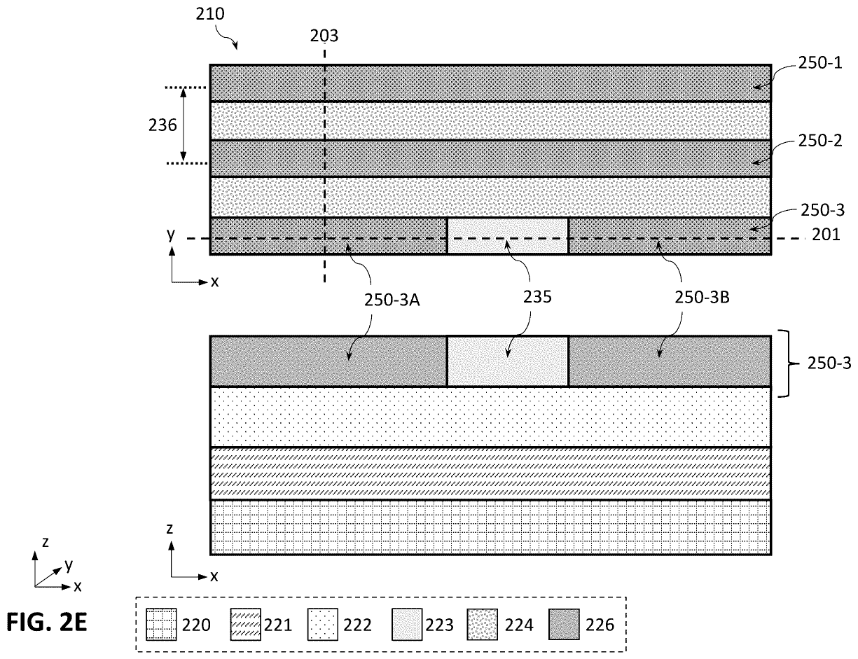

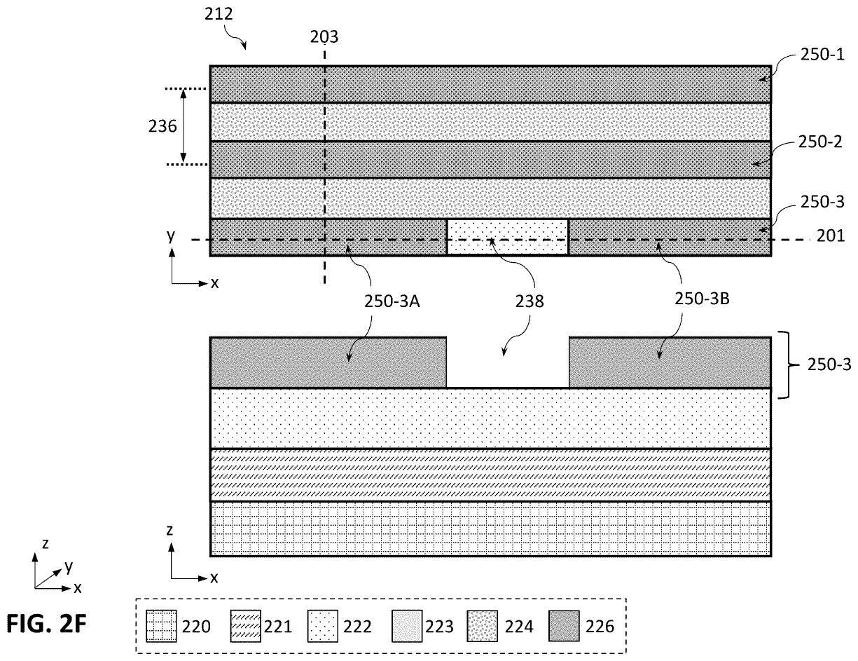

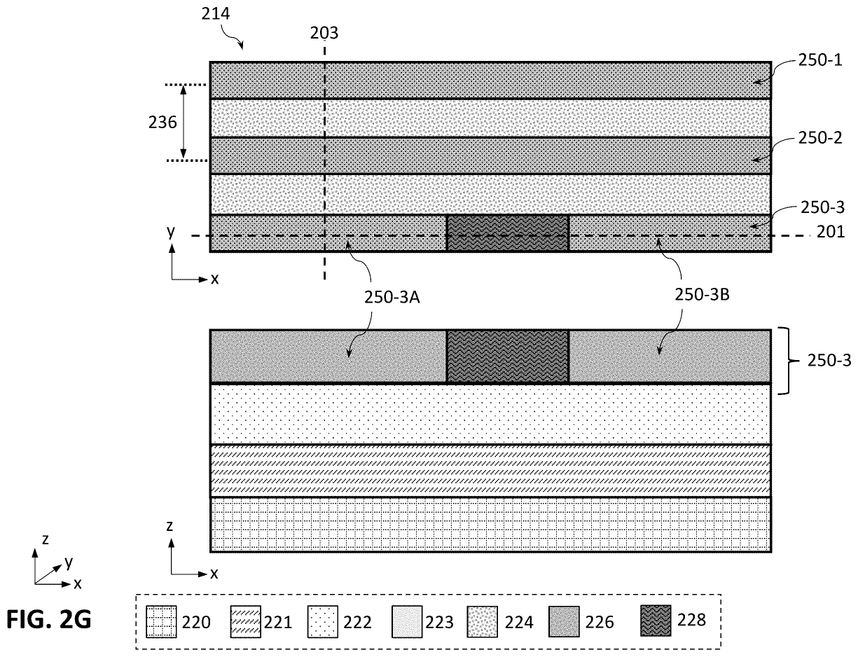

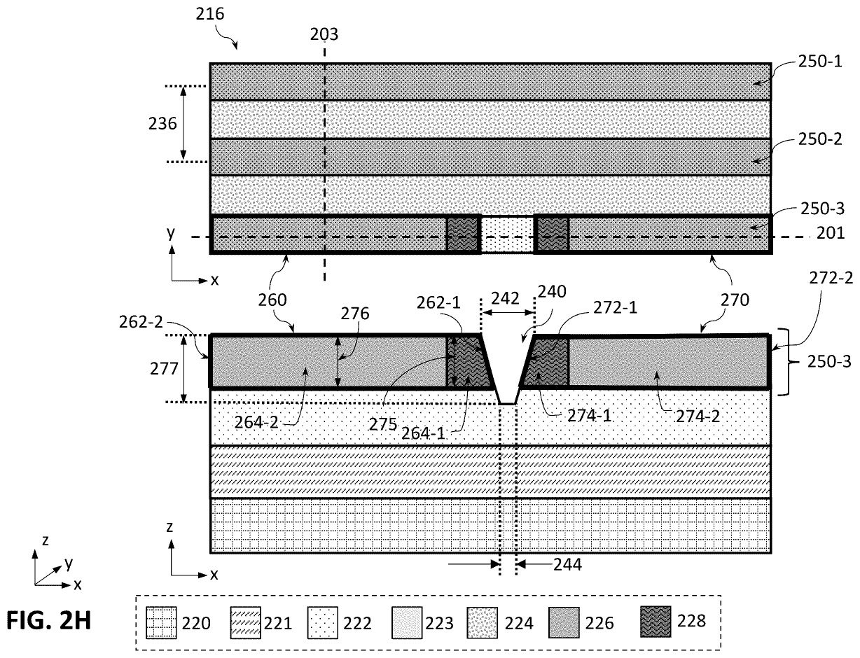

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 2A-2I, such a collection may be referred to herein without the letters, e.g., as “FIG. 2.” In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

In the drawings, some schematic illustrations of example structures of various structures, devices, and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices with hybrid metal lines as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with hybrid metal lines as described herein may be implemented in one or more components associated with an IC or/and between various such components. In various embodiments, components associated with an IC include, for example, transistors, diodes, power sources, resistors, capacitors, inductors, sensors, transceivers, transmitters, receivers, antennas, etc. Components associated with an IC may include those that are mounted on an IC, provided as an integral part of an IC, or those connected to an IC. The IC may be either analog or digital, or may include a combination of analog and digital circuitry, and may be used in a number of applications, such as microprocessors, optoelectronics, logic blocks, audio amplifiers, etc., depending on the components associated with the IC. In some embodiments, IC devices with hybrid metal lines as described herein may be included in a RFIC, which may, e.g., be included in any component associated with an IC of an RF receiver, an RF transmitter, or an RF transceiver, or any other RF device, e.g., as used in telecommunications within base stations (BS) or user equipment (UE) devices. Such components may include, but are not limited to, power amplifiers, RF switches, RF filters (including arrays of RF filters, or RF filter banks), or impedance tuners. In some embodiments, the IC devices with hybrid metal lines as described herein may be employed as part of a chipset for executing one or more related functions in a computer.

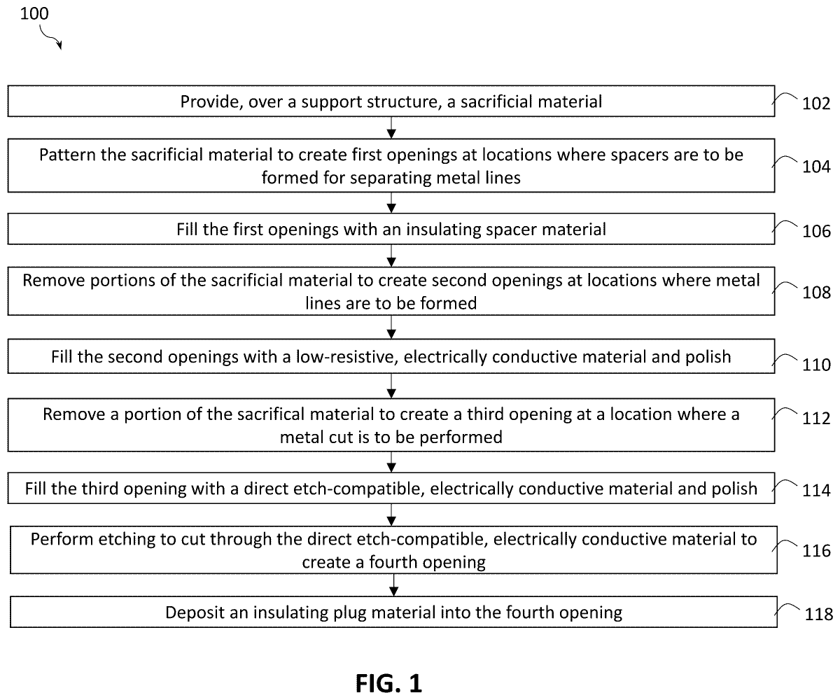

FIG. 1 provides a flow diagram of an example method 100 of fabricating an IC device with hybrid metal lines using plug last metal cut techniques, in accordance with various embodiments of the present disclosure.

Although the operations of the method 100 are illustrated once each and in a particular order, the operations may be performed in any suitable order and repeated as desired. For example, one or more operations may be performed in parallel to manufacture, substantially simultaneously, an IC device with hybrid metal lines as described herein. In another example, the operations may be performed in a different order to reflect the structure of a particular device assembly in which hybrid metal lines as described herein will be included.

In addition, the example manufacturing method 100 may include other operations not specifically shown in FIG. 1, such as various cleaning or planarization operations as known in the art. For example, in some embodiments, a support structure, as well as layers of various other materials subsequently deposited thereon, may be cleaned prior to, after, or during any of the processes of the method 100 described herein, e.g., to remove oxides, surface-bound organic and metallic contaminants, as well as subsurface contamination. In some embodiments, cleaning may be carried out using e.g., chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the arrangements/devices described herein may be planarized prior to, after, or during any of the processes of the method 100 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Various operations of the method 100 may be illustrated with reference to the example embodiments shown in FIGS. 2A-2I, illustrating top-down views and cross-sectional side views for various stages in the manufacture of an example IC device that includes hybrid metal lines, in accordance with some embodiments. For example, results of different processes of the method 100 are illustrated as an IC device 202 shown in FIG. 2A as an example result of a process 102 of the method 100, an IC device 204 shown in FIG. 2B as an example result of a process 104 of the method 100, and so on until an IC device 218 shown in FIG. 21 as an example result of a process 118 of the method 100. In particular, the top illustration of each of FIGS. 2A-2I shows a top-down view of the IC device (i.e., the view of the x-y plane of the reference coordinate system x-y-z shown in FIGS. 2A-2I), while the bottom illustration shows a cross-sectional side view of the IC device (i.e., the view of the x-z plane of the reference coordinate system, e.g., the cross-section taken along a plane shown in FIG. 2A with a dashed line 201).

A number of elements referred to in the description of FIGS. 2A-2I with reference numerals are illustrated in these figures with different patterns, with a legend showing the correspondence between the reference numerals and patterns being provided at the bottom of each drawing page containing FIGS. 2A-2I. For example, the legend illustrates that FIGS. 2A-2I use different patterns to show a support structure 220, a front-end-of-line (FEOL) device layer, an insulating interlayer material 222, a sacrificial material 223, an insulating spacer material 224, a low-resistive, electrically conductive material 226, a direct etch-compatible, electrically conductive material 228, an insulating plug material 230, etc. Furthermore, although a certain number of a given element may be illustrated in some of FIGS. 2A-2I (e.g., three metal lines 250, individually shown as 250-1, 250-2, and 250-3, or the metal line 250-3 separating into two hybrid metal lines 260 and 270), this is simply for ease of illustration, and more, or less, than that number may be included in an IC device fabricated according to the method 100. Still further, various IC device views shown in FIGS. 2A-2I are intended to show relative arrangements of various elements therein, and that various IC devices, or portions thereof, may include other elements or components that are not illustrated (e.g., transistor portions, various components that may be in electrical contact with any of the bottom metal line, the top metal line, and the horizontal via in between, etc.).

Turning to FIG. 1, the method 100 may begin with a process 102 that includes providing, over a support structure, a sacrificial material. An IC device 202, depicted in FIG. 2A, illustrates an example result of the process 102. As shown in FIG. 2A, the IC device 202 may include a support structure 220 and a layer of a sacrificial material 223 provided over the support structure 220.

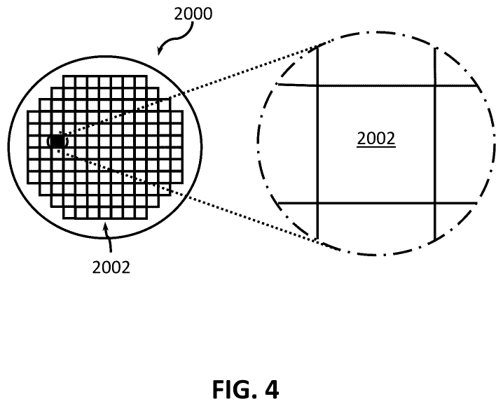

Implementations of the present disclosure may be formed or carried out on any suitable support structure, such as a substrate, a die, a wafer, or a chip. The support structure may, e.g., be the wafer 2000 of FIG. 4, discussed below, and may be, or be included in, a die, e.g., the singulated die 2002 of FIG. 4, discussed below. The support structure may be a semiconductor substrate composed of semiconductor material systems including, for example, N-type or P-type materials systems. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. Although a few examples of materials from which the support structure may be formed are described here, any material that may serve as a foundation upon which an IC may be built falls within the spirit and scope of the present disclosure. As used herein, the term “support structure” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure may provide material “support” in that, e.g., the IC devices/structures described herein are build based on the semiconductor materials of the support structure. However, in some embodiments, the support structure of the IC devices described herein may provide mechanical support.

In some embodiments, the sacrificial material 223 may be a low-k or high-k dielectric including, but not limited to, dielectric materials that include elements such as hafnium, silicon, oxygen, nitrogen, titanium, tantalum, lanthanum, aluminum, zirconium, barium, strontium, yttrium, lead, scandium, niobium, and zinc. Further examples of dielectric materials that may be used in the sacrificial material 223 may include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the sacrificial material 223 may be a low-k dielectric material. Examples of the low-k dielectric materials that may be used as the sacrificial material 223 include, but are not limited to, silicon dioxide, carbon-doped oxide, silicon nitride, fused silica glass (FSG), and organosilicates such as silsesquioxane, siloxane, and organosilicate glass. Other examples of low-k dielectric materials that may be used as the sacrificial material 223 include organic polymers such as polyimide, benzocyclobutene, polynorbornenes, perfluorocyclobutane, or polytetrafluoroethylene (PTFE). Still other examples of low-k dielectric materials that may be used as the sacrificial material 223 include silicon-based polymeric dielectrics such as hydrogen silsesquioxane (HSQ) and methylsilsesquioxane (MSQ). Other examples of low-k materials that may be used in the sacrificial material 223 include various porous dielectric materials, such as for example porous silicon dioxide or porous carbon-doped silicon dioxide, where voids or pores are created in a dielectric in order to reduce the overall dielectric constant of the material, since voids or pores can have a dielectric constant of nearly 1.

In various embodiments, the sacrificial material 223 may be deposited over the support structure 220 in the process 102 using a deposition technique such as, but not limited to, spin-coating, dip-coating, atomic layer deposition (ALD), chemical vapor deposition (CVD), or physical vapor deposition (PVD) (e.g., evaporative deposition, magnetron sputtering, or e-beam deposition).

In various embodiments, the IC device 202 may further include an FEOL device layer 221 and a layer of insulating interlayer material 222 over the support structure 220, where the insulating interlayer material 222 may be between the layer of sacrificial material 223 and the FEOL device layer 221. Accordingly, the layer of sacrificial material 223 may be formed over the layer of insulating interlayer material 222. As will be discussed more fully below, the sacrificial material 223 may facilitate fabrication of hybrid metal lines (e.g., in a BEOL interconnect layer).

In some embodiments, the FEOL layer 221 may be a compute logic layer in that it may include various logic layers, circuits, and devices (e.g., logic transistors) to drive and control a logic IC.

In some embodiments, the insulating interlayer material 222 may be a low-k or high-k dielectric including, but not limited to, dielectric materials that include elements such as hafnium, silicon, oxygen, nitrogen, titanium, tantalum, lanthanum, aluminum, zirconium, barium, strontium, yttrium, lead, scandium, niobium, and zinc. Further examples of dielectric materials that may be used in the insulating interlayer material 222 may include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the insulating interlayer material 222 may be a low-k dielectric material. Examples of the low-k dielectric materials that may be used as the insulating interlayer material 222 include, but are not limited to, silicon dioxide, carbon-doped oxide, silicon nitride, FSG, and organosilicates such as silsesquioxane, siloxane, and organosilicate glass. Other examples of low-k dielectric materials that may be used as the insulating interlayer material 222 include organic polymers such as polyimide, benzocyclobutene, polynorbornenes, perfluorocyclobutane, or polytetrafluoroethylene (PTFE). Still other examples of low-k dielectric materials that may be used as the insulating interlayer material 222 include silicon-based polymeric dielectrics such as hydrogen silsesquioxane (HSQ) and methylsilsesquioxane (MSQ). Other examples of low-k materials that may be used in the insulating interlayer material 222 include various porous dielectric materials, such as for example porous silicon dioxide or porous carbon-doped silicon dioxide, where voids or pores are created in a dielectric in order to reduce the overall dielectric constant of the material, since voids or pores can have a dielectric constant of nearly 1.

The method 100 may further include a process 104, which may include patterning the sacrificial material to create first openings (e.g., line trenches) at locations where spacers are to be formed for separating metal lines. An IC device 204, depicted in FIG. 2B, illustrates an example result of the process 104. As shown in FIG. 2B, the IC device 204 may include a plurality of first openings 232 (individually shown as 232-1 and 232-2). The plurality of first openings 232 may be elongated openings extending along an axis 201 (e.g., the x axis of the x-y-z coordinate system shown in FIG. 2B) over the support structure 220. The plurality of first openings 232 may be spaced apart from each other along an axis 203 (e.g., the y axis of the x-y-z coordinate system shown in FIG. 2B) that is about perpendicular to the axis 201.

In some embodiments, as part of the patterning in the process 102, a mask may be provided over the sacrificial material 223. The mask may include any suitable mask material (e.g., any conventional lithographic stack of materials, which may, e.g., include a carbon hard mask) in which openings may be formed, defining the approximate locations, geometry, and dimensions of the openings 232 in the sacrificial material 223. The mask may be patterned in the process 104 using any suitable technique, such as photolithography or electron-beam lithography. The patterns formed in the mask may then be transferred to the sacrificial material 223, e.g., by etching the sacrificial material 223 through the openings patterned in the mask, to form the openings 232 in the sacrificial material 223. In some embodiments, the process 104 may include performing an anisotropic etch to form the openings 232 in the sacrificial material 223. Such an anisotropic etch may include an etch that uses etchants in a form of e.g., chemically active ionized gas (i.e., plasma) using e.g., bromine (Br) and chloride (Cl) based chemistries. In some embodiments, during the etch of the process 102, the IC structure may be heated to elevated temperatures, e.g., to temperatures between about room temperature and 200 degrees Celsius, including all values and ranges therein, to promote that byproducts of the etch are made sufficiently volatile to be removed from the surface. In some embodiments, the anisotropic etch of the process 104 may include a dry etch, such as RF reactive ion etch (RIE) or inductively coupled plasma (ICP) RIE.

The method 100 may then include a process 106 that involves filling the first openings in the sacrificial material with an insulating spacer material. An IC device 206, depicted in FIG. 2C, illustrates an example result of the process 106. As shown in FIG. 2C, the IC device 206 may include an insulating spacer material 224 deposited in the first openings 232.

In some embodiments, the insulating spacer material 224 may be a low-k or high-k dielectric including, but not limited to, dielectric materials that include elements such as hafnium, silicon, oxygen, nitrogen, titanium, tantalum, lanthanum, aluminum, zirconium, barium, strontium, yttrium, lead, scandium, niobium, and zinc. Further examples of dielectric materials that may be used in the insulating spacer material 224 may include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the insulating spacer material 224 may be a low-k dielectric material. Examples of the low-k dielectric materials that may be used as the insulating spacer material 224 include, but are not limited to, silicon dioxide, carbon-doped oxide, silicon nitride, FSG, and organosilicates such as silsesquioxane, siloxane, and organosilicate glass. Other examples of low-k dielectric materials that may be used as the insulating spacer material 224 include organic polymers such as polyimide, benzocyclobutene, polynorbornenes, perfluorocyclobutane, or polytetrafluoroethylene (PTFE). Still other examples of low-k dielectric materials that may be used as the insulating spacer material 224 include silicon-based polymeric dielectrics such as hydrogen silsesquioxane (HSQ) and methylsilsesquioxane (MSQ). Other examples of low-k materials that may be used in the insulating spacer material 224 include various porous dielectric materials, such as for example porous silicon dioxide or porous carbon-doped silicon dioxide, where voids or pores are created in a dielectric in order to reduce the overall dielectric constant of the material, since voids or pores can have a dielectric constant of nearly 1. In general, the insulating spacer material 224 may be any suitable insulating material.

In some embodiments, the process 106 may include a conformal deposition technique such as ALD may be used to deposit the insulating spacer material 224. However, in other embodiments, any other suitable deposition techniques may be used to provide the insulating spacer material 224 within the first openings 232 in the sacrificial material 223, such as spin-coating, dip-coating, physical vapor deposition (PVD) (e.g., evaporative deposition, magnetron sputtering, or e-beam deposition), or CVD.

The method 100 may then include a process 108 that involves removing portions of the sacrificial material to create second openings (e.g., line openings or line trenches) at locations where metal lines are to be formed. An IC device 208, depicted in FIG. 2D, illustrates an example result of the process 108. As shown in FIG. 2D, the IC device 208 may include a plurality of second openings 234 (individually shown as 234-1, 234-2, and 234-3). The plurality of second openings 234 may be elongated openings extending along the axis 201 over the support structure 220. That is, the plurality of second openings 234 may be in the form of elongated line openings (line trenches). The plurality of second openings 234 may alternate with the filled first openings 232 (filled with the insulating spacer material 224).

As further shown in FIG. 2D, the opening 234-3 is non-continuous. More specifically, the opening 243-3 may include two separate sub-openings 234-3A and 234-3B spaced apart from each other by a portion 235 of sacrificial material 223. The process 108 may specifically preserve the portion 235 of sacrificial material 223 between the sub-openings 234-3A and 234-3B. As will be discussed more fully below, the location of the preserved portion 235 may be used for forming a plug through which a metal cut may be performed to form hybrid metal lines. In some embodiments, the process 108 may include performing any suitable etch, e.g., an anisotropic etch as described above, to form the second openings 234.

The method 100 may then include a process 110 that involves filling the second openings with a low-resistive, electrically conductive material and polishing the IC device to remove excess of the low-resistive, electrically conductive material. An IC device 210, depicted in FIG. 2E, illustrates an example result of the process 110. As shown in FIG. 2E, the IC device 210 may include a low-resistive, electrically conductive material 226 deposited in the second openings 234. In some embodiments, the low-resistive, electrically conductive material 226 may include copper.

In some embodiments, the process 110 may include, first, depositing the low-resistive, electrically conductive material 226 everywhere over the IC device 208, including in the openings 234 and over the insulating spacer material 224, and then performing a suitable polishing process, e.g., CMP, to remove excess of the low-resistive, electrically conductive material 226, e.g., to expose the top surface of the portion 235 of sacrificial material 223. By virtue of being deposited in the second openings 234, the low-resistive, electrically conductive material 226 will adapt to the shapes of the second openings 234. The second openings 234 filled with the low-resistive, electrically conductive material 226 form metal lines 250. The metal lines 250 are individually shown as 250-1, 250-2, and 250-3, where the metal line 250-3 may include two separate (disjoint) segments 250-3A and 250-3B separated by the portion 235 of sacrificial material 223. As shown in FIG. 2D, the metal lines 250 may extend along the axis 201 over the support structure 220 and spaced apart from each other along the axis 203 by the insulating spacer material 224. Accordingly, along the axis 201, the sidewalls of the metal lines 250 may be in contact with the insulating spacer material 224. In some instances, the metal lines 250 may be substantially parallel with one another, and the spacing between a nearest adjacent pair of metal lines 250 (e.g., the metal lines 250-1 and 250-2) may be defined by a pitch 236, which is the center-to-center distance (along the axis 203) between the closest adjacent metal lines 250. In some embodiments, the pitch 236 may be less than 50 nm (e.g., between about 16 and 50 nm, 20 and 45 nm, or 20 and 36 nm).

In various embodiments, the low-resistive, electrically conductive material 226 may be deposited in the second openings 234 in the process 110 using a deposition technique such as, but not limited to, ALD, CVD, PVD, plasma enhanced CVD (PECVD), or electroplating as discussed above.

The method 100 may then include a process 112 that involves removing a portion of the sacrificial material (the portion 235 of sacrificial material 223 preserved in the process 108) to create a third opening at a location where a metal cut is to be performed. An IC device 212, depicted in FIG. 2F, illustrates an example result of the process 112. As shown in FIG. 2F, the IC device 212 may include a third opening 238 in the metal line 250-3, where the removal of the portion 235 of the sacrificial material may expose a top surface of the insulating interlayer material 222. In some embodiments, the process 112 may include performing any suitable etch, e.g., an anisotropic etch as described above, to form the third opening 238.

The method 100 may then include a process 114 that involves filling the third opening in the metal line with a direct etch-compatible, electrically conductive material and polishing the IC device to remove excess of the direct etch-compatible, electrically conductive material. An IC device 214, depicted in FIG. 2G, illustrates an example result of the process 114. As shown in FIG. 2G, the IC device 214 may include a direct etch-compatible, electrically conductive material 228 deposited in the third opening 238 (created in the process 114). That is, the portions 250-3A and 250-3B of the metal line 250-3 may be spaced apart by the portion 235 of the direct etch-compatible, electrically conductive material 228. The direct etch-compatible, electrically conductive material 228 may be suitable for etching to form short or narrow cuts (e.g., with an opening width less than 35 nm).

In some embodiments, the direct etch-compatible, electrically conductive material 228 can include tungsten, molybdenum, or ruthenium. In some embodiments, the direct etch-compatible, electrically conductive material 228 can have a higher resistivity than the low-resistive, electrically conductive material 226. In general, the direct etch-compatible, electrically conductive material 228 may be any suitable metal that can be etched directly and cleanly to form short or narrow metal cut (e.g., with an opening dimension less than 35 nm).

In various embodiments, the direct etch-compatible, electrically conductive material 228 may be deposited in the third opening 238 in the process 114 using a deposition technique such as, but not limited to, ALD, CVD, PVD, PECVD, or electroplating as discussed above.

The method 100 may then include a process 116 that involves performing etching to cut through the direct etch-compatible, electrically conductive material to create a fourth opening. In some instances, the etching performed at the process 116 is a non-selective etch, and thus the etching may extend through the direct etch-compatible, electrically conductive material into the support structure, resulting in the removal of a portion of the support structure as well. An IC device 216, depicted in FIG. 2H, illustrates an example result of the process 116. As shown in FIG. 2H, the IC device 216 may include a fourth opening 240 through the direct etch-compatible, electrically conductive material 228 into a portion of the insulating interlayer material 222 (e.g., exposing a portion of the insulating interlayer material 222). The fourth opening 240 may have a shape that tapers down towards the support structure 220. For instance, the fourth opening 240 may have a cross-sectional sideview with a substantially trapezoidal shape, where along the axis 201, a dimension 242 of the opening 240 further away from the support structure 220 may be greater than a dimension 244 of the opening 240 closer to the support structure 220. In some embodiments, along the axis 201, a dimension of a widest portion of the opening 240 is less than 35 nanometers (e.g., between about 5 and 20 nm or 3 and 25 nm). That is, the dimension 242 (at the top of the opening 250) may be 35 nm or less.

The opening 240 may separate the metal line 250-3 into two metal lines (or two segments of metal lines), a first metal line 260 (a first segment) and a second metal line 270 (a second segment) extending along the axis 201 on opposite sides of the opening 240. The first metal line 260 may have a first end 262-1 and a second end 262-2, where a portion 264-1 of the first metal line 260 at the first end 262-1 may include the direct etch-compatible, electrically conductive material 228 and another portion 264-2 of the first metal line 260 (e.g., remaining portion of the first metal line 260) may include the low-resistive, electrically conductive material 226. The portion 264-2 may correspond to the segment 250-3A shown in FIGS. 2E-2G. Further, at the first end 262-1 of the first metal line 260, at least a portion of the low-resistive, electrically conductive material 226 may be in contact with a portion of the direct etch-compatible, electrically conductive material 228. Accordingly, the first metal line 260 may be referred to as a hybrid metal line. In some examples, the first metal line 260 may include the low-resistive, electrically conductive material 226 at the second end 262-2 as shown. In other examples, the first metal line 260 may include the direct etch-compatible, electrically conductive material 228 at the second end 262-2, for example, when the metal line 250-3 includes another metal line segment adjacent to the second end 262-2 and another metal cut is performed to form the second end 262-2.

In a similar way, the second metal line 270 may have a first end 272-1 and a second end 272-2, where the first end 272-1 of the second metal line 270 is closer to the first end 262-1 of the first metal line 260 than the second end 272-1 of the second metal line 270. Further, a portion 274-1 of the second metal line 270 at the third end 272-1 may include the direct etch-compatible, electrically conductive material 228 and another portion 264-2 of the second metal line 270 (e.g., remaining portion of the second metal line 270 corresponding to the segment 250-3B shown in FIGS. 2E-2G) may include the low-resistive, electrically conductive material 226. Accordingly, the second metal line 270 is another hybrid metal line. In some examples, the second metal line 270 may include the low-resistive, electrically conductive material 226 at the second end 272-2 as shown. In other examples, the second metal line 270 may include the direct etch-compatible, electrically conductive material 228 at the at the second end 272-2, for example, when the metal line 250-3 includes another metal line segment adjacent to the second end 272-2 and another metal cut is performed to form the second end 272-2. Stated differently, a hybrid metal line such as the hybrid metal lines 260 or 270, may include different fill materials in different portions of the hybrid metal line. More specifically, a hybrid metal line may include one portion including a low-resistive, electrically conductive fill material (e.g., copper) and another portion including a direct etch-compatible, electrically conductive fill material (e.g., tungsten, molybdenum or ruthenium), where the another portion may be at an end of the hybrid metal line where a metal cut was performed.

In some examples, a metal line can further include a liner with the low-resistive, electrically conductive fill material in one portion and the direct etch-compatible, electrically conductive fill material in another portion. In some examples, a liner may be an adhesion liner and/or a barrier liner. In some examples, a liner may include one or more of tantalum, tantalum nitride, titanium nitride, tungsten carbide, and cobalt.

In some embodiments, a height 275 (e.g., a dimension along the z-axis) of the portion 264-1 of the first metal line 260 (first metal segment) having the direct etch-compatible, electrically conductive material 228 may be about the same as a height 276 (e.g., a dimension along the z-axis) of the other portion 264-2 of the first metal line 270 having the low-resistive, electrically conductive material 226. As discussed above, the etch performed in the process 116 may be a non-selective etch process. As such, the opening 240 may extend into a portion of the insulating interlayer material 222. Accordingly, a depth 277 (e.g., a dimension along the z-axis) of the opening 240 at a narrowest portion thereof may be greater than the height 275 of the portion 264-2 of the first metal line 260 and/or the height 276 of the portion 264-1 of the first metal line 260 having the low-resistive, electrically conductive material 228.

In some embodiments, the process 116 may include performing any suitable etch, e.g., an anisotropic etch as described above, to form the fourth opening 240. In some instances, the etch process that forms the opening 240 may be referred to as a final etch or a last metal cut since this may be the last etch process for forming the hybrid metal line. It is because of this metal cut being performed as a last metal cut process, the fourth opening 240 may have a V-shape or trapezoidal shape that tapers down towards the support structure 220.

The method 100 may then include a process 118 that involves depositing an insulating plug material into the fourth opening. An IC device 218, depicted in FIG. 21, illustrates an example result of the process 118. As shown in FIG. 21, the IC device 218 may include an insulating plug material 230 deposited in the fourth opening 240. That is, the fourth opening 240 may be at least partially filled with the insulating plug material 230. Further, because the fourth opening 240 may extend into a portion of the insulating interlayer material 222 as discussed above. Accordingly, the insulating plug material 230 may at least partially fill the portion of the insulating interlayer material 222, for example, completely separating the first metal line 260 from the second metal line 270. Stated differently, the first end 262-1 of the first metal line 260 and the first end 272-1 of the second metal line 270 are spaced apart from each other by the insulating plug material 230. Accordingly, at least a portion of the first metal line 260 (the hybrid metal line) at the first end 262-1 may be in contact with the insulating plug material 230. Similarly, at least a portion of the second metal line 270 (the hybrid metal line) at the first end 272-1 may be in contact with the insulating plug material 230.

In some embodiments, the insulating plug material 230 may be a low-k or high-k dielectric including, but not limited to, dielectric materials that include elements such as hafnium, silicon, oxygen, nitrogen, titanium, tantalum, lanthanum, aluminum, zirconium, barium, strontium, yttrium, lead, scandium, niobium, and zinc. Further examples of dielectric materials that may be used in the insulating plug material 230 may include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the insulating plug material 230 may be a low-k dielectric material. Examples of the low-k dielectric materials that may be used as the insulating plug material 230 include, but are not limited to, silicon dioxide, carbon-doped oxide, silicon nitride, FSG, and organosilicates such as silsesquioxane, siloxane, and organosilicate glass. Other examples of low-k dielectric materials that may be used as the insulating plug material 230 include organic polymers such as polyimide, benzocyclobutene, polynorbornenes, perfluorocyclobutane, or polytetrafluoroethylene (PTFE). Still other examples of low-k dielectric materials that may be used as the insulating plug material 230 include silicon-based polymeric dielectrics such as hydrogen silsesquioxane (HSQ) and methylsilsesquioxane (MSQ). Other examples of low-k materials that may be used in the insulating plug material 230 include various porous dielectric materials, such as for example porous silicon dioxide or porous carbon-doped silicon dioxide, where voids or pores are created in a dielectric in order to reduce the overall dielectric constant of the material, since voids or pores can have a dielectric constant of nearly 1. In general, the insulating plug material 230 may be any suitable insulating material (e.g., a dielectric material). In some embodiments, the insulating plug material 230 may be substantially the same as the insulating spacer material 224. In other embodiments, the insulating plug material 230 may be different from the insulating spacer material 224. In an example, the insulating plug material 230 may have a lower dielectric constant than the insulating spacer material 224.

In some embodiments, the process 106 may include a conformal deposition technique such as ALD may be used to deposit the insulating plug material 230. However, in other embodiments, any other suitable deposition techniques may be used to provide the insulating plug material 230 within the fourth opening 240, such as spin-coating, dip-coating, physical vapor deposition (PVD) (e.g., evaporative deposition, magnetron sputtering, or e-beam deposition), or CVD.

In some embodiments, a distance (e.g., the dimension 242) between the first end 262-1 of the first metal line 260 and the first end 272-1 of the second metal line 270 in a first plane parallel to the support structure 220 (e.g., a substrate) is greater than a distance (e.g., the dimension 244), along the axis 201, between the first end 262-1 of the first metal line 260 and the first end 272-1 of the second metal line 270 in a second plane parallel to the support structure 220 (or substrate), the second plane being closer to the support structure than the first plane.

While the method 100 illustrated in in FIGS. 1 and 2A-2I forms the hybrid metal lines 260 and 270 using a certain sequence (e.g., an additive fabrication technique), aspects are not limited thereto. For example, a subtractive fabrication technique may also be suitable for forming hybrid metal lines as discussed herein. In general, any suitable fabrication techniques can be used to provide a metal line 250-3 with direct etch-compatible, electrically conductive material 228 between segments 250-3A and 250-3B of low-resistive, electrically conductive material 226 (as shown in FIG. 2G) so that a last metal cut step may be performed (e.g., as discussed above with reference to the process 116 in which the direct etch-compatible, electrically conductive material 228 is etched) to create hybrid metal lines. Further, any suitable number of plug last metal cuts (e.g., 2, 3 or more) can be performed on a metal line to create any suitable number of hybrid metal lines (e.g., 3, 4 or more) similar to the hybrid metal lines 260 and 270.

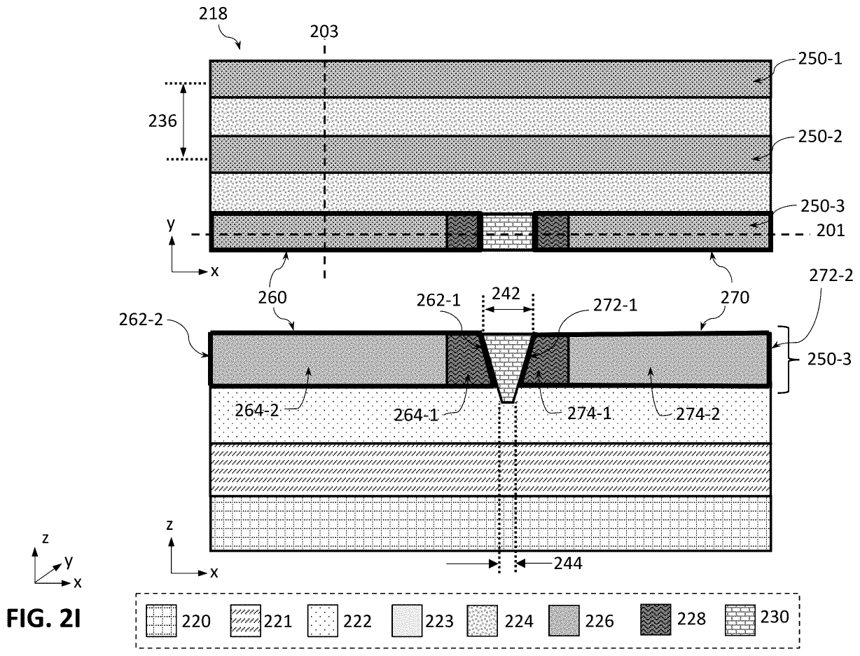

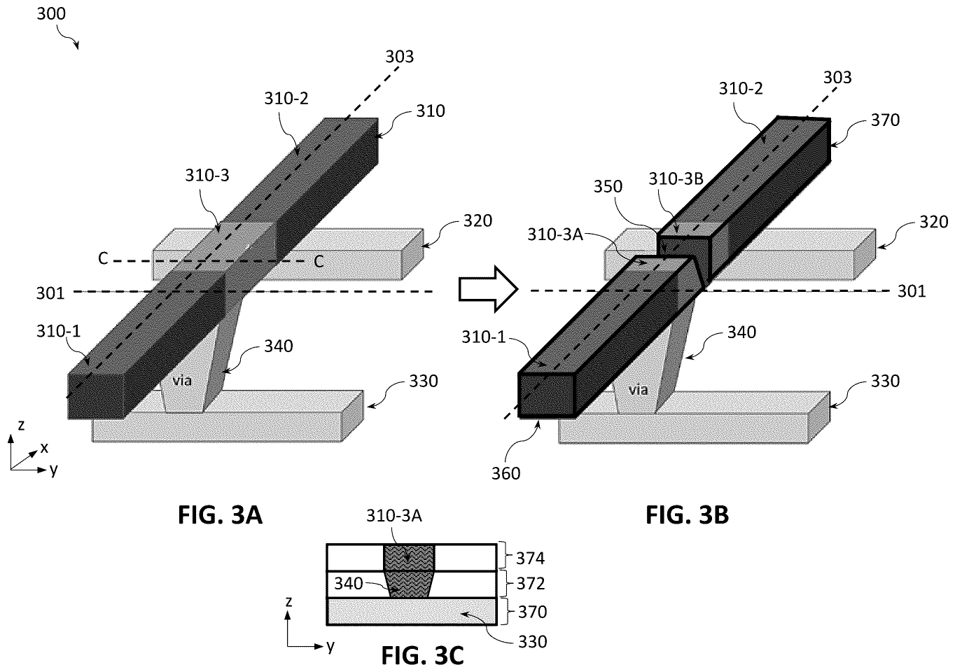

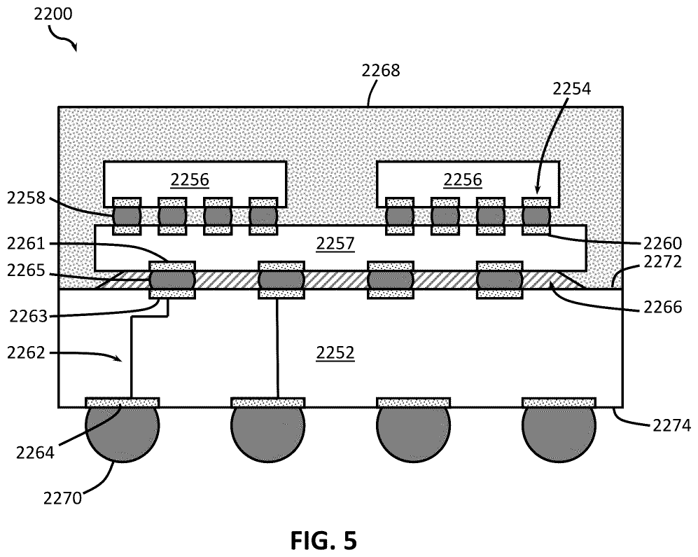

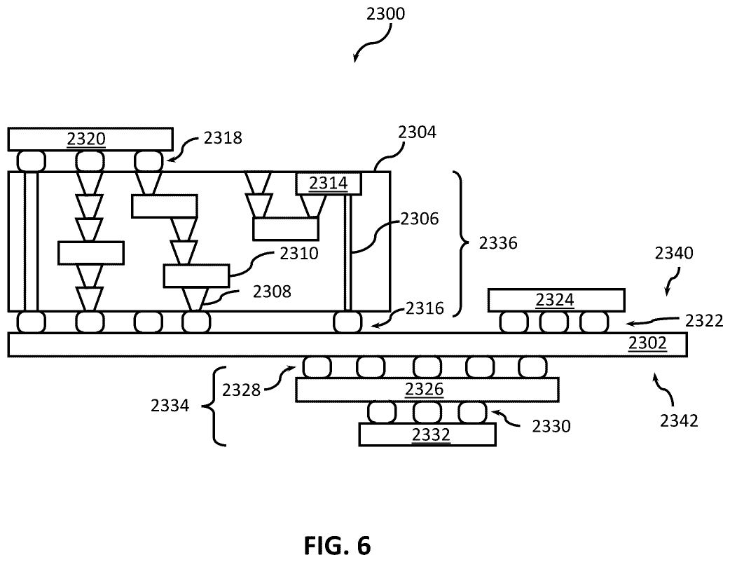

FIGS. 3A-3B illustrate perspective views and FIG. 3C illustrates a cross-sectional side view at various stages in the manufacture of an example IC device according to the method 100 of FIG. 1, in accordance with some embodiments, in accordance with various embodiments of the present disclosure. FIGS. 3A-3C may illustrate the process 116 of FIG. 1 in which a plug last metal cut step is performed on an interconnect structure 300. The interconnect structure 300 can be over a support structure (e.g., a substrate) in an IC device (e.g., the IC package 2200 of FIG. 5, the IC device assembly 2300 of FIG. 6). In the illustrated examples of FIGS. 3A-3C, the interconnect structure 300 may include metal lines 320 and 330 in a first metallization layer of the interconnect structure 300 and a metal line 310 in a second metallization layer (e.g., vertically above the first metallization layer along the z-axis of the reference coordinate system x-y-z shown in FIGS. 3A-3C) of the interconnect structure 300. In an example, the interconnect structure 300 may include a layer of interface layer dielectric (ILD) material between the first and second metallization layers so that the first and second metallization layers are electrically isolated from each other.

As shown in FIG. 3A, the metal lines 320 and 330 may extend along an axis 301 (e.g., the y axis of the reference coordinate system x-y-z shown in FIGS. 3A-3C). The metal line 310 may extend along an axis 303 (e.g., the x axis of the reference coordinate system x-y-z shown in FIGS. 3A-3C) that is about perpendicular to the axis 301. In general, the metal lines 310, 320, and 330 may be arranged in any suitable arrangement. The metal line 310 may include a first segment 310-1, a second segment 310-2, and third segment 310-3 in contact with the first segment 310-1 and the second segment 310-2. The first segment 310-1 and the second segment 310-2 may include a low-resistive, electrically conductive material (e.g., the low-resistive, electrically conductive material 226). In some examples, the low-resistive, electrically conductive material may include copper. In some examples, the metal lines 320 and 330 may also include copper for providing electrical paths in the IC device. The third segment 310-3 (the middle segment) may include a direct etch-compatible, electrically conductive material (e.g., the direct etch-compatible, electrically conductive material 228). In some examples, the direct etch-compatible, electrically conductive material may include, but are not limited to, at least one of tungsten, molybdenum, and ruthenium. As further shown in FIG. 3A, a via 340 made of one or more electrically conductive materials may be in contact with a portion of the third segment 310-3 in the second metallization layer and the metal line 330 in the first metallization layer, for example, to create an electrical connection as will be discussed more fully below.

As shown in FIG. 3B, a portion of the direct etch-compatible, electrically conductive material in the third segment 310-3 may be etched to form an opening 350, for example, using mechanisms as discussed above with reference to the process 116. The opening 350 may be similar to the opening 240, for example, having a V-shape or trapezoidal shape that tapers down towards the support structure. After creating the opening 350, the third segment 310-3 including the direct etch-compatible, electrically conductive material may be separated into two separate portions 310-3A and 310-3B. The portion 310-3A and the first segment 310-1 together may form one hybrid metal line 360 (e.g., similar to the first metal line 260 of FIG. 2), and the portion 310-3B and the second segment 310-2 together may form another, separate hybrid metal line 370 (e.g., similar to the first metal line 270 of FIG. 2). Accordingly, a hybrid metal line with the low-resistive, electrically conductive material being copper as disclosed herein may have remnant metals with direct etch capability around the cut locations on the same plane as the original copper metal line. As further shown in FIG. 3B, the via 340 may form an electrical connection between the metal line 330 and the hybrid metal line 360. In an example, the via 340 may comprise the same electrically conductive material as the third segment 310-3 at which the metal cut is performed. That is, the via 340 may include an electrically conductive material similar to the direct etch-compatible, electrically conductive material 228 discussed above. The via 340 may extend, vertically along the z-axis, between the metal line 330 and the hybrid metal line 360 (or more specifically at the end of the hybrid metal line 360 where the direct etch-compatible, electrically conductive material is included). In some instances, the via 340 may have a tapered shape, for example, tapering down from the second metallization layer to first metallization layer.

Subsequently, an insulator material (e.g., the insulating plug material 230) may be deposited in the opening 350 as discussed above with reference to the process 118.

FIG. 3C illustrates a cross-sectional side view of the interconnect structure 300 (i.e., the view of the z-y plane of the reference coordinate system, e.g., the cross-section taken along a plane shown in FIG. 3A with a dashed line C-C). As shown in FIG. 3C, the interconnect structure 300 includes the first metallization layer (shown by 370) and the second metallization layer (shown by 374) spaced apart by the ILD layer (shown by 372) along a direction of the z-axis. The cross-sectional side view shows the metal line 330 in the first metallization 370, the segment 310-3A (e.g., the end where the direct etch-compatible, electrically conductive material is included to facilitate the cut) of the hybrid metal line 360 in the second metallization layer 374. The cross-sectional side view further shows the via 340 extending between the metal line 330 and the segment 310-3A of the hybrid metal line 360. The via 340 may taper down from the second metallization layer 374 towards the first metallization layer 370.

In general, a method for fabricating hybrid metal lines using a plug last metal cut technique as described herein may include providing a support structure (e.g., the support structure 220). The method may further include providing a metal line (e.g., the metal line 310 or 250-3) over the support structure. The metal line may include a first segment, a second segment, and a third segment in contact with the first and second segments. The third segment may include a first electrically conductive material (e.g., the direct etch-compatible, electrically conductive material 228). The first and second segments may include a second electrically conductive material (e.g., the low-resistive, electrically conductive material 226). The method may further include removing a portion of the first electrically conductive material to create an opening through the third segment. The method may further include filling the opening with an insulator material (e.g., the insulating plug material 230).

IC devices with hybrid metal lines as disclosed herein may be included in any suitable electronic device. FIGS. 4-8 illustrate various examples of devices and components that may include at least one IC device with one or more hybrid metal lines as disclosed herein.

FIG. 4 illustrates top views of a wafer 2000 and dies 2002 that may include one or more IC devices with a hybrid metal line in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 5. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., IC devices including at least one hybrid metal line as described herein). After the fabrication of the semiconductor product is complete (e.g., after manufacture of at least one hybrid metal line as described herein, e.g., after manufacture of any embodiment of the IC devices shown in FIGS. 1-3, or any further embodiments of these devices, described herein), the wafer 2000 may undergo a singulation process in which each of the dies 2002 is separated from one another to provide discrete “chips” of the semiconductor product. In particular, IC devices with one or more hybrid metal lines as disclosed herein may take the form of the wafer 2000 (e.g., not singulated) or the form of the die 2002 (e.g., singulated). The die 2002 may include at least one hybrid metal line (e.g., the metal lines 260, 270), as well as, optionally, supporting circuitry to route electrical signals to the at least one hybrid metal line, as well as any other IC components. In some embodiments, the wafer 2000 or the die 2002 may implement an RF FE device, a memory device (e.g., a static random access memory (SRAM) device), a logic device (e.g., an AND, OR, NAND, or NOR gate), or any other suitable circuit element. Multiple ones of these devices may be combined on a single die 2002.

FIG. 5 is a side, cross-sectional view of an example IC package 2200 that may include one or more IC devices with a hybrid metal line in accordance with any of the embodiments disclosed herein. In some embodiments, the IC package 2200 may be a system-in-package (SiP).

As shown in FIG. 5, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 5 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 5 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 5 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 6.

The dies 2256 may take the form of any of the embodiments of the die 2002 discussed herein and may include any of the embodiments of an IC device having at least one hybrid metal line, e.g., any of the IC devices shown in FIGS. 2-3, or any further embodiments of at least one hybrid metal line, described herein. In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be RF FE dies and/or logic dies, including at least one hybrid metal line as described herein, one or more of the dies 2256 may be memory dies (e.g., high bandwidth memory), etc. In some embodiments, any of the dies 2256 may include at least one hybrid metal line, e.g., as discussed above; in some embodiments, at least some of the dies 2256 may not include any hybrid metal line.

The IC package 2200 illustrated in FIG. 5 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 5, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 6 is a cross-sectional side view of an IC device assembly 2300 that may include components having one or more IC devices implementing at least one hybrid metal line in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing at least one hybrid metal line in accordance with any of the embodiments disclosed herein; e.g., any of the IC packages discussed below with reference to the IC device assembly 2300 may take the form of any of the embodiments of the IC package 2200 discussed above with reference to FIG. 5 (e.g., may include at least one hybrid metal line in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 6 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 6), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 4), an IC device (e.g., the IC device of FIGS. 1-3), or any other suitable component. In particular, the IC package 2320 may include at least one hybrid metal line as described herein. Although a single IC package 2320 is shown in FIG. 6, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 6, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing at least one hybrid metal line as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 6 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

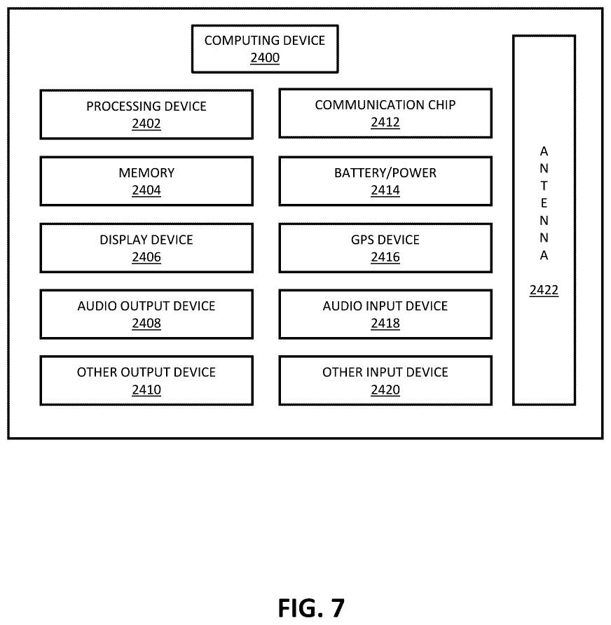

FIG. 7 is a block diagram of an example computing device 2400 that may include one or more components with one or more IC devices having at least one hybrid metal line in accordance with any of the embodiments disclosed herein. For example, any suitable ones of the components of the computing device 2400 may include a die (e.g., the die 2002 (FIG. 10)) including at least one hybrid metal line in accordance with any of the embodiments disclosed herein. Any of the components of the computing device 2400 may include an IC device (e.g., any embodiment of the IC device of FIGS. 1-3) and/or an IC package 2200 (FIG. 5). Any of the components of the computing device 2400 may include an IC device assembly 2300 (FIG. 6).

A number of components are illustrated in FIG. 7 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 7, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices with at least one hybrid metal line as described herein may be particularly advantageous for use within the one or more communication chips 2412, described above. For example, such IC devices with at least one hybrid metal line may be used to implement one or more of power amplifiers, low-noise amplifiers, filters (including arrays of filters and filter banks), switches, upconverters, downconverters, and duplexers, e.g., as a part of implementing an RF transmitter, an RF receiver, or an RF transceiver.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

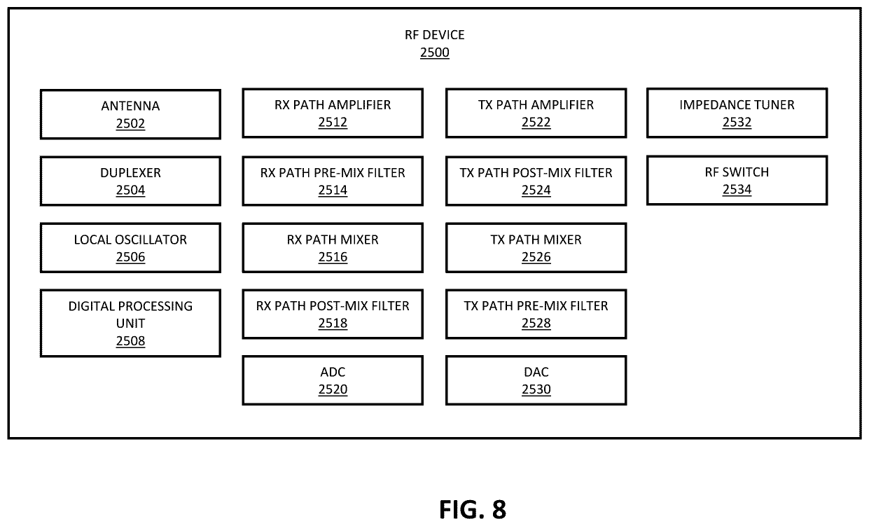

FIG. 8 is a block diagram of an example RF device 2500 that may include one or more components with one or more IC devices having at least one hybrid metal line in accordance with any of the embodiments disclosed herein. For example, any suitable ones of the components of the RF device 2500 may include a die (e.g., the die 2002 as described with reference to FIG. 6 or a die implementing the IC device as described with reference to FIGS. 1-3) including at least one hybrid metal line in accordance with any of the embodiments disclosed herein. Any of the components of the RF device 2500 may include an IC device (e.g., the IC device of FIGS. 1-3) and/or an IC package 2200 as described with reference to FIG. 5. Any of the components of the RF device 2500 may include an IC device assembly 2300 as described with reference to FIG. 6. In some embodiments, the RF device 2500 may be included within any components of the computing device 2400 as described with reference to FIG. 7, or may be coupled to any of the components of the computing device 2400, e.g., be coupled to the memory 2404 and/or to the processing device 2402 of the computing device 2400. In still other embodiments, the RF device 2500 may further include any of the components described with reference to FIG. 8, such as, but not limited to, the battery/power circuit 2414, the memory 2404, and various input and output devices as shown in FIG. 8.

In general, the RF device 2500 may be any device or system that may support wireless transmission and/or reception of signals in the form of electromagnetic waves in the RF range of approximately 3 kiloHertz (kHz) to 300 gigaHertz (GHz). In some embodiments, the RF device 2500 may be used for wireless communications, e.g., in a BS or a UE device of any suitable cellular wireless communications technology, such as GSM, WCDMA, or LTE. In a further example, the RF device 2500 may be used as, or in, e.g., a BS or a UE device of a mm-wave wireless technology such as fifth generation (5G) wireless (i.e., high frequency/short wavelength spectrum, e.g., with frequencies in the range between about 20 and 60 GHZ, corresponding to wavelengths in the range between about 5 and 15 millimeters). In yet another example, the RF device 2500 may be used for wireless communications using WiFi technology (e.g., a frequency band of 2.4 GHZ, corresponding to a wavelength of about 12 cm, or a frequency band of 5.8 GHZ, spectrum, corresponding to a wavelength of about 5 cm), e.g., in a WiFi-enabled device such as a desktop, a laptop, a video game console, a smart phone, a tablet, a smart TV, a digital audio player, a car, a printer, etc. In some implementations, a WiFi-enabled device may, e.g., be a node in a smart system configured to communicate data with other nodes, e.g., a smart sensor. Still in another example, the RF device 2500 may be used for wireless communications using Bluetooth technology (e.g., a frequency band from about 2.4 to about 2.485 GHz, corresponding to a wavelength of about 12 cm). In other embodiments, the RF device 2500 may be used for transmitting and/or receiving RF signals for purposes other than communication, e.g., in an automotive radar system, or in medical applications such as magneto-resonance imaging (MRI).

In various embodiments, the RF device 2500 may be included in frequency division duplexing (FDD) or time-domain duplex (TDD) variants of frequency allocations that may be used in a cellular network. In an FDD system, the uplink (i.e., RF signals transmitted from the UE devices to a BS) and the downlink (i.e., RF signals transmitted from the BS to the US devices) may use separate frequency bands at the same time. In a TDD system, the uplink and the downlink may use the same frequencies but at different times.

A number of components are illustrated in FIG. 8 as included in the RF device 2500, but any one or more of these components may be omitted or duplicated, as suitable for the application. For example, in some embodiments, the RF device 2500 may be an RF device supporting both of wireless transmission and reception of RF signals (e.g., an RF transceiver), in which case it may include both the components of what is referred to herein as a transmit (TX) path and the components of what is referred to herein as a receive (RX) path. However, in other embodiments, the RF device 2500 may be an RF device supporting only wireless reception (e.g., an RF receiver), in which case it may include the components of the RX path, but not the components of the TX path; or the RF device 2500 may be an RF device supporting only wireless transmission (e.g., an RF transmitter), in which case it may include the components of the TX path, but not the components of the RX path.

In some embodiments, some or all of the components included in the RF device 2500 may be attached to one or more motherboards. In some embodiments, some or all of these components are fabricated on a single die, e.g., on a single SoC die.

Additionally, in various embodiments, the RF device 2500 may not include one or more of the components illustrated in FIG. 8, but the RF device 2500 may include interface circuitry for coupling to the one or more components. For example, the RF device 2500 may not include an antenna 2502, but may include antenna interface circuitry (e.g., a matching circuitry, a connector and driver circuitry) to which an antenna 2502 may be coupled. In another set of examples, the RF device 2500 may not include a digital processing unit 2508 or a local oscillator 2506, but may include device interface circuitry (e.g., connectors and supporting circuitry) to which a digital processing unit 2508 or a local oscillator 2506 may be coupled.

As shown in FIG. 8, the RF device 2500 may include an antenna 2502, a duplexer 2504, a local oscillator 2506, a digital processing unit 2508. As also shown in FIG. 8, the RF device 2500 may include an RX path which may include an RX path amplifier 2512, an RX path pre-mix filter 2514, a RX path mixer 2516, an RX path post-mix filter 2518, and an analog-to-digital converter (ADC) 2520. As further shown in FIG. 8, the RF device 2500 may include a TX path which may include a TX path amplifier 2522, a TX path post-mix filter 2524, a TX path mixer 2526, a TX path pre-mix filter 2528, and a digital-to-analog converter (DAC) 2530. Still further, the RF device 2500 may further include an impedance tuner 2532 and an RF switch 2534. In various embodiments, the RF device 2500 may include multiple instances of any of the components shown in FIG. 8. The RX path amplifier 2512, the TX path amplifier 2522, the duplexer 2504, and the RF switch 2534 may be considered to form, or be a part of, an RF FE of the RF device 2500. The RX path mixer 2516 and the TX path mixer 2526 (possibly with their associated pre-mix and post-mix filters shown in FIG. 8) may be considered to form, or be a part of, an RF transceiver of the RF device 2500 (or of an RF receiver or an RF transmitter if only RX path or TX path components, respectively, are included in the RF device 2500).

The antenna 2502 may be configured to wirelessly transmit and/or receive RF signals in accordance with any wireless standards or protocols, e.g., Wi-Fi, LTE, or GSM, as well as any other wireless protocols that are designated as 3G, 4G, 5G, and beyond. If the RF device 2500 is an FDD transceiver, the antenna 2502 may be configured for concurrent reception and transmission of communication signals in separate, i.e., non-overlapping and non-continuous, bands of frequencies, e.g., in bands having a separation of, e.g., 20 MHz from one another. If the RF device 2500 is a TDD transceiver, the antenna 2502 may be configured for sequential reception and transmission of communication signals in bands of frequencies which may be the same, or overlapping for TX and RX paths. In some embodiments, the RF device 2500 may be a multi-band RF device, in which case the antenna 2502 may be configured for concurrent reception of signals having multiple RF components in separate frequency bands and/or configured for concurrent transmission of signals having multiple RF components in separate frequency bands. In such embodiments, the antenna 2502 may be a single wide-band antenna or a plurality of band-specific antennas (i.e., a plurality of antennas each configured to receive and/or transmit signals in a specific band of frequencies). In various embodiments, the antenna 2502 may include a plurality of antenna elements, e.g., a plurality of antenna elements forming a phased antenna array (i.e., a communication system or an array of antennas that may use a plurality of antenna elements and phase shifting to transmit and receive RF signals). Compared to a single-antenna system, a phased antenna array may offer advantages such as increased gain, ability of directional steering, and simultaneous communication. In some embodiments, the RF device 2500 may include more than one antenna 2502 to implement antenna diversity. In some such embodiments, the RF switch 2534 may be deployed to switch between different antennas.

An output of the antenna 2502 may be coupled to the input of the duplexer 2504. The duplexer 2504 may be any suitable component configured for filtering multiple signals to allow for bidirectional communication over a single path between the duplexer 2504 and the antenna 2502. The duplexer 2504 may be configured for providing RX signals to the RX path of the RF device 2500 and for receiving TX signals from the TX path of the RF device 2500.

The RF device 2500 may include one or more local oscillators 2506, configured to provide local oscillator signals which may be used for downconversion of the RF signals received by the antenna 2502 and/or upconversion of the signals to be transmitted by the antenna 2502.

The RF device 2500 may include the digital processing unit 2508, which may include one or more processing devices. In some embodiments, the digital processing unit 2508 may be implemented as the processing device 2402 shown in FIG. 7, descriptions of which are provided above (when used as the digital processing unit 2508, the processing device 2402 may, but does not have to, implement any of the IC devices as described herein, e.g., IC devices having at least one hybrid metal line in accordance with any of the embodiments disclosed herein). The digital processing unit 2508 may be configured to perform various functions related to digital processing of the RX and/or TX signals. Examples of such functions include, but are not limited to, decimation/downsampling, error correction, digital downconversion or upconversion, DC offset cancellation, automatic gain control, etc. Although not shown in FIG. 8, in some embodiments, the RF device 2500 may further include a memory device, e.g., the memory device 2404 as described with reference to FIG. 8, configured to cooperate with the digital processing unit 2508. When used within, or coupled to, the RF device 2500, the memory device 2404 may, but does not have to, implement any of the IC devices as described herein, e.g., IC devices having at least one hybrid metal line in accordance with any of the embodiments disclosed herein.

Turning to the details of the RX path that may be included in the RF device 2500, the RX path amplifier 2512 may include a low-noise amplifier (LNA). An input of the RX path amplifier 2512 may be coupled to an antenna port (not shown) of the antenna 2502, e.g., via the duplexer 2504. The RX path amplifier 2512 may amplify the RF signals received by the antenna 2502.

An output of the RX path amplifier 2512 may be coupled to an input of the RX path pre-mix filter 2514, which may be, e.g., a harmonic or band-pass filter, configured to filter received RF signals that have been amplified by the RX path amplifier 2512.

An output of the RX path pre-mix filter 2514 may be coupled to an input of the RX path mixer 2516, also referred to as a downconverter. The RX path mixer 2516 may include two inputs and one output. A first input may be configured to receive the RX signals, which may be current signals, indicative of the signals received by the antenna 2502 (e.g., the first input may receive the output of the RX path pre-mix filter 2514). A second input may be configured to receive local oscillator signals from one of the local oscillators 2506. The RX path mixer 2516 may then mix the signals received at its two inputs to generate a downconverted RX signal, provided at an output of the RX path mixer 2516. As used herein, downconversion refers to a process of mixing a received RF signal with a local oscillator signal to generate a signal of a lower frequency. In particular, the downconverter 2516 may be configured to generate the sum and/or the difference frequency at the output port when two input frequencies are provided at the two input ports. In some embodiments, the RF device 2500 may implement a direct-conversion receiver (DCR), also known as homodyne, synchrodyne, or zero-IF receiver, in which case the RX path mixer 2516 may be configured to demodulate the incoming radio signals using local oscillator signals whose frequency is identical to, or very close to the carrier frequency of the radio signal. In other embodiments, the RF device 2500 may make use of downconversion to an intermediate frequency (IF). IFs may be used in superheterodyne radio receivers, in which a received RF signal is shifted to an IF, before the final detection of the information in the received signal is done. Conversion to an IF may be useful for several reasons. For example, when several stages of filters are used, they can all be set to a fixed frequency, which makes them easier to build and to tune. In some embodiments, the RX path mixer 2516 may include several such stages of IF conversion.

Although a single RX path mixer 2516 is shown in the RX path of FIG. 8, in some embodiments, the RX path mixer 2516 may be implemented as a quadrature downconverter, in which case it would include a first RX path mixer and a second RX path mixer. The first RX path mixer may be configured for performing downconversion to generate an in-phase (I) downconverted RX signal by mixing the RX signal received by the antenna 2502 and an in-phase component of the local oscillator signal provided by the local oscillator 2506. The second RX path mixer may be configured for performing downconversion to generate a quadrature (Q) downconverted RX signal by mixing the RX signal received by the antenna 2502 and a quadrature component of the local oscillator signal provided by the local oscillator 2506 (the quadrature component is a component that is offset in phase from the in-phase component of the local oscillator signal by 90 degrees). The output of the first RX path mixer may be provided to a I-signal path, and the output of the second RX path mixer may be provided to a Q-signal path, which may be substantially 90 degrees out of phase with the I-signal path.

The output of the RX path mixer 2516 may, optionally, be coupled to the RX path post-mix filter 2518, which may be low-pass filters. In case the RX path mixer 2516 is a quadrature mixer that implements the first and second mixers as described above, the in-phase and quadrature components provided at the outputs of the first and second mixers respectively may be coupled to respective individual first and second RX path post-mix filters included in the filter 2518.

The ADC 2520 may be configured to convert the mixed RX signals from the RX path mixer 2516 from analog to digital domain. The ADC 2520 may be a quadrature ADC that, similar to the RX path quadrature mixer 2516, may include two ADCs, configured to digitize the downconverted RX path signals separated in in-phase and quadrature components. The output of the ADC 2520 may be provided to the digital processing unit 2508, configured to perform various functions related to digital processing of the RX signals so that information encoded in the RX signals can be extracted.

Turning to the details of the TX path that may be included in the RF device 2500, the digital signal to later be transmitted (TX signal) by the antenna 2502 may be provided, from the digital processing unit 2508, to the DAC 2530. Similar to the ADC 2520, the DAC 2530 may include two DACs, configured to convert, respectively, digital I- and Q-path TX signal components to analog form.

Optionally, the output of the DAC 2530 may be coupled to the TX path pre-mix filter 2528, which may be a low-pass filter (or a pair of filters, in case of quadrature processing) configured to filter out, from the analog TX signals output by the DAC 2530, the signal components outside of the desired band. The digital TX signals may then be provided to the TX path mixer 2526, which may also be referred to as an upconverter. Similar to the RX path mixer 2516, the TX path mixer 2526 may include a pair of TX path mixers, for in-phase and quadrature component mixing. Similar to the first and second RX path mixers that may be included in the RX path, each of the TX path mixers of the TX path mixer 2526 may include two inputs and one output. A first input may receive the TX signal components, converted to the analog form by the respective DAC 2530, which are to be upconverted to generate RF signals to be transmitted. The first TX path mixer may generate an in-phase (I) upconverted signal by mixing the TX signal component converted to analog form by the DAC 2530 with the in-phase component of the TX path local oscillator signal provided from the local oscillator 2506 (in various embodiments, the local oscillator 2506 may include a plurality of different local oscillators, or be configured to provide different local oscillator frequencies for the mixer 2516 in the RX path and the mixer 2526 in the TX path). The second TX path mixer may generate a quadrature phase (Q) upconverted signal by mixing the TX signal component converted to analog form by the DAC 2530 with the quadrature component of the TX path local oscillator signal. The output of the second TX path mixer may be added to the output of the first TX path mixer to create a real RF signal. A second input of each of the TX path mixers may be coupled the local oscillator 2506.

Optionally, the RF device 2500 may include the TX path post-mix filter 2524, configured to filter the output of the TX path mixer 2526.

The TX path amplifier 2522 may be a power amplifier (PA), configured to amplify the upconverted RF signal before providing it to the antenna 2502 for transmission.

In various embodiments, any of the RX path pre-mix filter 2514, the RX path post-mix filter 2518, the TX post-mix filter 2524, and the TX pre-mix filter 2528 may be implemented as RF filters. In some embodiments, each of such RF filters may include one or more, typically a plurality of, resonators (e.g., film bulk acoustic resonators (FBARs), Lamb wave resonators, and/or contour-wave resonators), arranged, e.g., in a ladder configuration. An individual resonator of an RF filter may include a layer of a piezoelectric material such as aluminum nitride (AlN), enclosed between a bottom electrode and a top electrode, with a cavity provided around a portion of each electrode in order to allow a portion of the piezoelectric material to vibrate during operation of the filter. In some embodiments, an RF filter may be implemented as a plurality of RF filters, or a filter bank. A filter bank may include a plurality of RF resonators which may be coupled to a switch, e.g., the RF switch 2534, configured to selectively switch any one of the plurality of RF resonators on and off (i.e., activate any one of the plurality of RF resonators), in order to achieve desired filtering characteristics of the filter bank (i.e., in order to program the filter bank). For example, such a filter bank may be used to switch between different RF frequency ranges when the RF device 2500 is, or is included in, a BS or in a UE device. In another example, such a filter bank may be programmable to suppress TX leakage on the different duplex distances.

The impedance tuner 2532 may include any suitable circuitry, configured to match the input and output impedances of the different RF circuitries to minimize signal losses in the RF device 2500. For example, the impedance tuner 2532 may include an antenna impedance tuner. Being able to tune the impedance of the antenna 2502 may be particularly advantageous because antenna's impedance is a function of the environment that the RF device 2500 is in, e.g. antenna's impedance changes depending on, e.g., if the antenna is held in a hand, placed on a car roof, etc.

As described above, the RF switch 2534 may be used to selectively switch between a plurality of instances of any one of the components shown in FIG. 8, in order to achieve desired behavior and characteristics of the RF device 2500. For example, in some embodiments, an RF switch may be used to switch between different antennas 2502. In other embodiments, an RF switch may be used to switch between a plurality of RF resonators (e.g., by selectively switching RF resonators on and off) of any of the filters included in the RF device 2500.

In various embodiments, IC devices including one or more hybrid metal lines as described herein may be particularly advantageous when used in any of the duplexer 2504, RX path amplifier 2512, RX path pre-mix filter 2514, RX path post-mix filter 2518, TX path amplifier 2522, TX path pre-mix filter 2528, TX path post-mix filter 2524, impedance tuner 2532, and/or RF switch 2534.

The RF device 2500 provides a simplified version and, in further embodiments, other components not specifically shown in FIG. 8 may be included. For example, the RX path of the RF device 2500 may include a current-to-voltage amplifier between the RX path mixer 2516 and the ADC 2520, which may be configured to amplify and convert the downconverted signals to voltage signals. In another example, the RX path of the RF device 2500 may include a balun transformer for generating balanced signals. In yet another example, the RF device 2500 may further include a clock generator, which may, e.g., include a suitable phase-locked loop (PLL), configured to receive a reference clock signal and use it to generate a different clock signal which may then be used for timing the operation of the ADC 2520, the DAC 2530, and/or which may also be used by the local oscillator 2506 to generate the local oscillator signals to be used in the RX path or the TX path.

The following paragraphs provide various examples of the embodiments disclosed herein.

Example 1 includes an integrated circuit (IC) device, including a substrate; and a metal line extending, along an axis, over the substrate, where the metal line has a first end and a second end along the axis, a portion of the metal line at the first end includes a first electrically conductive material, another portion of the metal line includes a second electrically conductive material, and the second electrically conductive material is different from the first electrically conductive material.

Example 2 provides the IC device according to claim 1, where the second electrically conductive material includes copper.

Example 3 provides the IC device according to any one of claims 1-2, where the first electrically conductive material is a material compatible with direct etch processes.

Example 4 provides the IC device according to any one of claims 1-2, where the first electrically conductive material includes tungsten, molybdenum or ruthenium.

Example 5 provides the IC device according to any one of claims 1-2, where the another portion of the metal line is a portion of the metal line at the second end.

Example 6 provides the IC device according to any one of claims 1-5, where the axis is a first axis, the IC device further includes a plurality of metal lines extending, along the first axis, over the substrate and spaced apart from each other along a second axis by an insulator material, and the metal line is one of the plurality of metal lines.

Example 7 provides the IC device according to claim 6, where a pitch of the plurality of metal lines is less than 50 nanometers.

Example 8 provides the IC device according to any one of claims 1-7, where the metal line is a first metal line, and the IC device further includes a second metal line extending, along the axis, over the substrate, where the second metal line has a first end and a second end along the axis, the first end of the second metal line is closer to the first end of the first metal line than the second end of the second metal line, a portion of the second metal line at the first end of the second metal line includes the first electrically conductive material, and another portion of the second metal line includes the second electrically conductive material.

Example 9 provides the IC device according to claim 8, where a distance between the first end of the first metal line and the first end of the second metal line in a first plane parallel to the substrate is greater than a distance between the first end of the first metal line and the first end of the second metal line in a second plane parallel to the substrate, the second plane being closer to the substrate than the first plane.

Example 10 provides the IC device according to any one of claims 8-9, where the first end of the first metal line and the first end of the second metal line are spaced apart from each other by an insulator material.

Example 11 provides the IC device according to claim 10, where the insulator material is a first insulator material, the IC device further includes a second insulator material between the substrate and the metal line, and the first insulator material extends into a portion of the second insulator material.

Example 12 provides the IC device according to any one of claims 10-11, where the insulator material is a first insulator material, and a sidewall of the first metal line along the axis is in contact with a second insulator material.

Example 13 provides the IC device according to claim 12, where the first insulator material is different from the second insulator material.

Example 14 provides the IC device according to claim 12, where the first insulator material is the same as the second insulator material.

Example 15 provides the IC device according to claim 12, where the first insulator material has a lower dielectric constant than the second insulator material.

Example 16 includes an integrated circuit (IC) device including a support structure; a metal line over the support structure, the metal line extending along an axis; and an opening extending through the metal line, the opening including an insulator material and separating the metal line into a first segment and a second segment, where the first segment and the second segment extend along the axis on opposite sides of the opening, and where the opening tapers down towards the support structure.

Example 17 provides the IC device according to claim 16, where along the axis, a dimension of a widest portion of the opening is less than 35 nanometers.

Example 18 provides the IC device according to any one of claims 16-17, where the insulator material is a first insulator material, the IC device further includes a second insulator material between the support structure and the metal line, and the opening extends into a portion of the second insulator material.

Example 19 provides the IC device according to claim 18, where the first insulator material at least partially fills the portion of the second insulator material.

Example 20 provides the IC device according to any one of claims 18-19, where the first segment has a first end and a second end along the axis, a portion of the first segment at the first end includes a first electrically conductive material in contact with the first insulator material, another portion of the first segment includes a second electrically conductive material, and the second electrically conductive material is different from the first electrically conductive material.

Example 21 provides the IC device according to claim 20, where the second electrically conductive material includes copper, and the first electrically conductive material includes tungsten, molybdenum or ruthenium.

Example 22 provides the IC device according to any one of claims 20-21, where the second segment has a first end and a second end along the axis, a portion of the second segment at the first end of the second segment includes the first electrically conductive material in contact with the first insulator material, and another portion of the second segment includes the second electrically conductive material.

Example 23 includes a method of manufacturing an integrated circuit (IC) device, the method including providing a metal line over a support structure, the metal line including a first segment, a second segment, and a third segment in contact with the first and second segments, where the first and second segments include a first electrically conductive material, the third segment includes a second electrically conductive material, and the second electrically conductive material is different than the first electrically conductive material; removing a portion of the second electrically conductive material to create an opening through the third segment; and depositing an insulator material into the opening.

Example 24 provides the method according to claim 23, where the removing the portion of the second electrically conductive material includes performing a non-selective etch.

Example 25 provides the IC device according to any one of the preceding claims, where the IC device includes or is a part of a central processing unit.

Example 26 provides the IC device according to any one of the preceding claims, where the IC device includes or is a part of a memory device.

Example 27 provides the IC device according to any one of the preceding claims, where the IC device further includes a plurality of memory cells, each of the memory cells including a storage element.

Example 28 provides the IC device according to claim 27, where the storage element is one of a capacitor, a magnetoresistive material, a ferroelectric material, or a resistance-changing material.

Example 29 provides the IC device according to any one of the preceding claims, where the IC device includes or is a part of a logic circuit.

Example 30 provides the IC device according to any one of the preceding claims, where the IC device includes or is a part of input/output circuitry.

Example 31 provides the IC device according to any one of the preceding claims, where the IC device includes or is a part of a field programmable gate array transceiver.

Example 32 provides the IC device according to any one of the preceding claims, where the IC device includes or is a part of a field programmable gate array logic.

Example 33 provides the IC device according to any one of the preceding claims, where the IC device includes or is a part of a power delivery circuitry.

Example 34 provides the IC device according to any one of the preceding claims, where the IC device includes or is a part of a III-V amplifier.

Example 35 provides the IC device according to any one of the preceding claims, where the IC device includes or is a part of Peripheral Component Interconnect Express circuitry or Double Data Rate transfer circuitry.

Example 36 includes an IC package that includes a die including an IC device according to any one of the preceding claims; and a further IC component, coupled to the die.

Example 37 provides the IC package according to claim 36, where the further IC component includes one of a package substrate, an interposer, or a further IC support structure.

Example 38 includes a computing device that includes a carrier substrate and an IC device, coupled to the carrier substrate, where the IC device is an IC device according to any one of the preceding claims, or the IC device is included in the IC package according to any one of claims 37-38.

Example 39 provides the computing device according to claim 38, where the computing device is a wearable or handheld computing device.

Example 40 provides the computing device according to claim 38 or 39, where the computing device further includes one or more communication chips and an antenna.

Example 41 provides the computing device according to any one of claims 38-40, where the carrier substrate is a motherboard.

Example 42 includes a method of manufacturing an IC device, the method including providing the IC device according to any one of the preceding claims.

1. An integrated circuit (IC) device, comprising:
a substrate; and
a first metal line and a second metal line extending, along an axis, over the substrate, wherein:
the first metal line has a first end and a second end along the axis,
a portion of the first metal line at the first end comprises a first electrically conductive material,
another portion of the first metal line comprises a second electrically conductive material,
the second metal line has a first end and a second end along the axis,
the first end of the second metal line is closer to the first end of the first metal line than the second end of the second metal line,
a portion of the second metal line at the first end of the second metal line includes the first electrically conductive material, and
another portion of the second metal line includes the second electrically conductive material, and
the second electrically conductive material is different from the first electrically conductive material.

2. The IC device according to claim 1, wherein the second electrically conductive material comprises copper.

3. The IC device according to claim 1, wherein the first electrically conductive material is a material compatible with direct etch processes.

4. The IC device according to claim 1, wherein the first electrically conductive material comprises tungsten, molybdenum or ruthenium.

5. The IC device according to claim 1, wherein the another portion of the first metal line is a portion of the first metal line at the second end.

6. The IC device according to claim 1, wherein:
the axis is a first axis,
the IC device further comprises:
a plurality of metal lines extending, along the first axis, over the substrate and spaced apart from each other along a second axis by an insulator material, and
the first metal line is one of the plurality of metal lines.

7. The IC device according to claim 6, wherein a pitch of the plurality of metal lines is less than 50 nanometers.

8. The IC device according to claim 1, wherein a distance between the first end of the first metal line and the first end of the second metal line in a first plane parallel to the substrate is greater than a distance between the first end of the first metal line and the first end of the second metal line in a second plane parallel to the substrate, the second plane being closer to the substrate than the first plane.

9. The IC device according to claim 1, wherein the first end of the first metal line and the first end of the second metal line are spaced apart from each other by an insulator material.

10. The IC device according to claim 9, wherein:
the insulator material is a first insulator material,
the IC device further comprises a second insulator material between the substrate and the first metal line, and
the first insulator material extends into a portion of the second insulator material.

11. The IC device according to claim 1, further comprising:
a first metallization layer including the first metal line and the second metal line;
a second metallization layer including a third metal line; and
a via extending between the third metal line and the first end of the first metal line, wherein the via comprises the first electrically conductive material.

12. An integrated circuit (IC) device comprising:
a support structure;
a metal line over the support structure, the metal line extending along an axis; and
an opening extending through the metal line, the opening comprising an insulator material and separating the metal line into a first segment and a second segment,
wherein the first segment and the second segment extend along the axis on opposite sides of the opening, and wherein the opening tapers down towards the support structure.

13. The IC device according to claim 12, wherein along the axis, a dimension of a widest portion of the opening is less than 35 nanometers.

14. The IC device according to claim 12, wherein the insulator material is a first insulator material, the IC device further comprises a second insulator material between the support structure and the metal line, and the opening extends into a portion of the second insulator material.

15. The IC device according to claim 14, wherein the first insulator material at least partially fills the portion of the second insulator material.

16. The IC device according to claim 14, wherein:
the first segment has a first end and a second end along the axis,
a portion of the first segment at the first end comprises a first electrically conductive material in contact with the first insulator material,
another portion of the first segment comprises a second electrically conductive material, and
the second electrically conductive material is different from the first electrically conductive material.

17. The IC device according to claim 16, wherein:
the second electrically conductive material comprises copper, and
the first electrically conductive material comprises tungsten, molybdenum or ruthenium.

18. The IC device according to claim 16, wherein:
the second segment has a first end and a second end along the axis,
a portion of the second segment at the first end of the second segment comprises the first electrically conductive material in contact with the first insulator material, and
another portion of the second segment comprises the second electrically conductive material.

19. A method of manufacturing an integrated circuit (IC) device, the method comprising:
providing a metal line over a support structure, the metal line comprising a first segment, a second segment, and a third segment in contact with the first and second segments, wherein:
the first and second segments comprise a first electrically conductive material,
the third segment comprises a second electrically conductive material, and
the second electrically conductive material is different from the first electrically conductive material;
removing a portion of the second electrically conductive material to create an opening through the third segment; and
depositing an insulator material into the opening.

20. The method according to claim 19, wherein the removing the portion of the second electrically conductive material includes performing a non-selective etch.
